(19) United States
(12) Patent Application Publication
(10) Pub. No.: US 2024/0256630 A1
(43) Pub. Date: Aug. 1, 2024

(54) FILTER DESIGN METHOD AND IIR-TYPE ALL-PASS FILTER

(71) Applicant: Alps Alpine Co., Ltd., Tokyo (JP)

(72) Inventor: Yukio OTAKI, Miyagi-ken (JP)

(21) Appl. No.: 18/630,423

(22) Filed: Apr. 9, 2024

Related U.S. Application Data
(63) Continuation of application No. PCT/JP2022/037998, filed on Oct. 12, 2022.

(30) Foreign Application Priority Data
Dec. 28, 2021 (JP) 2021-214342

(51) Int. Cl. G06F 17/14

(52) U.S. Cl. CPC G06F 17/142

(57) ABSTRACT

A filter design method and an IIR-type all-pass filter that enable reduction of the number of components is provided. In the filter design method, a computer designs an IIR-type all-pass filter including N (N is an integer of 4 or more) signal processors connected between an input terminal and an output terminal, a group delay count M of the IIR-type all-pass filter has the relationship “M=N−3” with respect to the order N defined by the number N of signal processors, and the computer executes a process of setting the filter coefficients with even-numbered indices to zero when the order N is an odd number and the index is 1, and setting the filter coefficients with odd-numbered indices to zero when the order N is an even number and the index is 0.

### CLAIM OF PRIORITY

This application is a Continuation of International Application No. PCT/JP2022/037998 filed on Oct. 12, 2022, which claims benefit of Japanese Patent Application No. 2021-214342 filed on Dec. 28, 2021. The entire contents of each application noted above are hereby incorporated by reference.

### BACKGROUND OF THE INVENTION

### 1. Field of the Invention

The present disclosure relates to a filter design method and an infinite impulse response (IIR)-type all-pass filter.

### 2. Description of the Related Art

In general, a medium that records a design program for designing on a computer an IIR digital filter including a delay device and a phase equalizer connected in parallel, in accordance with the Remez algorithm using a given filter order, a passband end frequency, a stopband end frequency and a weight function has been used. The design program inputs a passband amplitude difference, a stopband attenuation amount, a passband end frequency, and a stopband end frequency as parameters indicating transmission characteristics of the filter when an empirical function representing the relationship between a ratio x of a phase inclination which is approximated to a predetermined phase difference relative to the delay device to a phase inclination of a passband of the filter and the stopband attenuation amount y of the filter is assigned to the delay device, calculates the weight function and the filter order based on the parameters and the empirical function, and performs filter design in accordance with the Remez algorithm using the weight function and the filter order (refer to Japanese Unexamined Patent Application Publication No. 10-187662, for example).

The general IIR digital filter design programs do not allow for reduction in the number of components.

### SUMMARY OF THE INVENTION

Therefore, the present disclosure provides a filter design method and an IIR-type all-pass filter that enable reduction of the number of components.

According to an aspect of the present disclosure, in a filter design method in which a computer designs an IIR-type all-pass filter including N (N is an integer of 4 or more) signal processors connected between an input terminal and an output terminal, a group delay count M of the IIR-type all-pass filter has the relationship “M=N−3” with respect to the order N defined by the number N of signal processors, and the computer executes a process including accepting inputs of the order N and a bandwidth B of the IIR-type all-pass filter, setting a frequency low limit fl and a frequency high limit fh which are symmetrical using the bandwidth B, calculating filter coefficients ai (i=0 to N) including N filter coefficients a1 to aN by which outputs of the N signal processors are multiplied and a filter coefficient a0 by which an output of a delay device of the N-th signal processor counting from the input terminal is multiplied such that the filter coefficients ai realizes a π/2 shift characteristic, and calculating the filter coefficients ai based on the Remez algorithm until a change in frequency at which an amplitude value of a complex amplitude error indicates an extreme value converges to or below a predetermined value, extracting a maximum value of the filter coefficients ai and an index i of the filter coefficient ai that gives the maximum value (imax), and setting the filter coefficients ai with even-numbered indices i to zero when the order N is an odd number and the index imax is 1, and setting the filter coefficients ai with odd-numbered indices i to zero when the order N is an even number and the index imax is 0.

### BRIEF DESCRIPTION OF THE DRAWINGS

FIG. 1 is a diagram illustrating a receiver according to an embodiment;

FIG. 2A is a diagram illustrating an example of a configuration of an IIR-type all-pass filter according to the embodiment;

FIG. 2B is a diagram illustrating an example of another configuration of the IIR-type all-pass filter according to the embodiment;

FIG. 3 is a graph of an example of a frequency characteristic of a cumulative phase of the IIR-type all-pass filter;

FIG. 4 is a graph of an example of a frequency characteristic of a phase difference between I and Q signals and an amplitude of the Q signal;

FIG. 5 is a graph of an example of a frequency characteristic of a phase error of the Q signal;

FIG. 6 is a table of an example of the relationship among a combination of an order N and a group delay count M, a frequency low limit, a frequency high limit, a design bandwidth, a phase error, and filter coefficients;

FIG. 7 is a diagram illustrating an IIR-type all-pass filter with a simplified circuit configuration;

FIG. 8 is a diagram illustrating an IIR-type all-pass filter with a simplified circuit configuration;

FIG. 9 is a diagram illustrating an IIR-type all-pass filter with a simplified circuit configuration;

FIGS. 10A to 10C are graphs of examples of the frequency characteristic of an IIR-type all-pass filter with an order N of 9 and M of N−2;

FIGS. 11A to 11C are graphs of examples of the frequency characteristic of an IIR-type all-pass filter with an order N of 9 and M of N−1;

FIG. 12 is a diagram illustrating an example of a configuration of an IIR-type all-pass filter (N=10) according to the embodiment;

FIG. 13 is a table of an example of the relationship among a combination of an order N and a group delay count M, a frequency low limit, a frequency high limit, a design bandwidth, a phase error, and filter coefficients;

FIGS. 14A to 14C are graphs of examples of the frequency characteristic of an IIR-type all-pass filter with an order N of 10 and M of N−3;

FIGS. 15A to 15C are graphs of examples of the frequency characteristic of an IIR-type all-pass filter with an order N of 10 and M of N−2;

FIGS. 16A to 16C are graphs of examples of the frequency characteristic of an IIR-type all-pass filter with an order N of 10 and M of N−1;

FIG. 17 is a diagram illustrating a computer system;

FIG. 18 is a block diagram illustrating a configuration of an important portion in a main body of the computer system;

FIG. 19 is a functional block diagram of a filter design device;

FIG. 20 is a flowchart of a process performed by the filter design device;

FIG. 21 is a flowchart of a process performed by the filter design device; and

FIG. 22 is a flowchart of a process performed by the filter design device.

### DESCRIPTION OF THE PREFERRED EMBODIMENTS

The following describes a filter design method according to the present disclosure and an embodiment to which an IIR-type all-pass filter is applied.

### Embodiment

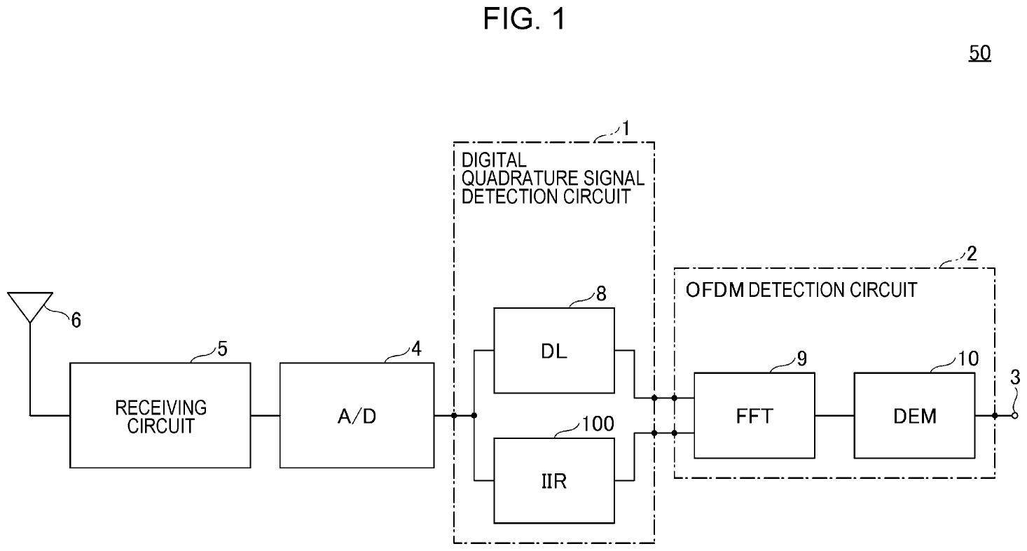

FIG. 1 is a diagram illustrating a receiver 50 according to an embodiment. The receiver 50 includes a digital quadrature signal detection circuit 1, an orthogonal frequency division multiplex (OFDM) detection circuit 2, a detection signal output terminal 3, an analog/digital converter (A/D) 4, a receiving circuit 5, and a receiving antenna 6.

The digital quadrature signal detection circuit 1 includes an infinite impulse response (IIR)-type all-pass filter 100 which is an infinite impulse response digital filter, and a digital signal delay circuit (DL) 8. The orthogonal frequency division multiplex detection circuit 2 includes a fast Fourier transform (FFT) circuit 9 and an orthogonal frequency division multiplex demodulation circuit (DEM) 10. The IIR-type all-pass filter 100 shifts an input digital signal by 90 degrees, and the digital signal delay circuit 8 provides an input digital signal with a signal delay equal to a signal group delay amount of the IIR-type all-pass filter 100. The phase shifting indicates shifting of a phase of a signal.

The receiving circuit 5 has an input terminal connected to the receiving antenna 6 and an output terminal connected to an input terminal of the analog/digital converter 4. In the digital quadrature signal detection circuit 1, the IIR-type all-pass filter 100 has an input terminal directly connected to an output terminal of the analog/digital converter 4 and an output terminal connected to a first input terminal of the fast Fourier transform circuit 9. The digital signal delay circuit (DL) 8 has an input terminal directly connected to the output terminal of the analog/digital converter 4 and an output terminal connected to a second input terminal of the fast Fourier transform circuit 9. In the orthogonal frequency division multiplex detection circuit 2, the orthogonal frequency division multiplex demodulation circuit 10 has an input terminal connected to an output terminal of the fast Fourier transform circuit 9 and an output terminal connected to the detection signal output terminal 3.

When a digital signal is received at the receiving antenna 6, the digital signal is supplied to the receiving circuit 5 as a received signal. The receiving circuit 5 amplifies the received signal, then performs frequency-mixing on the amplified received signal and a local oscillator signal to form a frequency-mixed signal, extracts an intermediate frequency (IF) signal from the formed frequency-mixed signal, and outputs the obtained intermediate frequency signal to the analog/digital converter 4. The analog/digital converter 4 performs analog/digital conversion on the input intermediate frequency signal, and independently outputs a digital signal to be supplied to the digital quadrature signal detection circuit 1 (sampling frequency fs) from the output terminal.

In the digital quadrature signal detection circuit 1, the IIR-type all-pass filter 100 shifts a phase of the supplied digital signal by 90 degrees to generate a Q signal, and outputs the Q signal to the orthogonal frequency division multiplex detection circuit 2. The digital signal delay circuit 8 generates an I signal by delaying the input digital signal by a signal delay amount which is equal to a signal group delay amount given to the digital signal to be shifted by 90° in the IIR-type all-pass filter 100, and outputs the signal to the orthogonal frequency division multiplex detection circuit 2.

In the orthogonal frequency division multiplex detection circuit 2, the fast Fourier transform circuit 9 performs fast Fourier transform processing using the I and Q signals, and supplies a Fourier transform processing signal to the orthogonal frequency division multiplex demodulation circuit 10. The orthogonal frequency division multiplex demodulation circuit 10 performs demodulation processing for digital modulation, such as quadrature phase shift keying (QPSK), on the supplied Fourier transform processing signal, and supplies a resultant demodulated signal to the detection signal output terminal 3.

### Configuration of IIR-Type All-Pass Filter 100

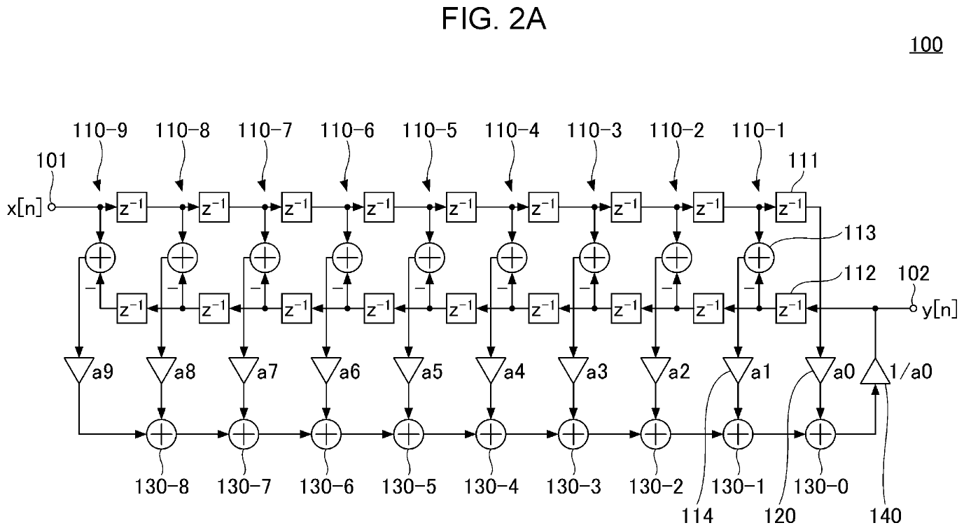

FIG. 2A is a diagram illustrating an example of a configuration of the IIR-type all-pass filter 100 according to the embodiment. The IIR-type all-pass filter 100 includes an input terminal 101, an output terminal 102, N signal processors 110, an amplifier 120, N adders 130, and an amplifier 140. N is an integer larger than or equal to 4. As an example, nine signal processors 110-1 to 110-9 and nine adders 130-0 to 130-8 are illustrated when N is 9 in FIG. 2A. In the following, the N signal processors 110 may be referred to as signal processors 110-1 to 110-N.

The integer N represents the number of signal processors 110 and an order N of the IIR-type all-pass filter 100. The order N is defined by the number of signal processors 110. When the signal processors 110-1 to 110-N are not specifically distinguished from one to another, they are simply referred to as signal processors 110. In FIG. 2A, the configuration of the IIR-type all-pass filter 100 is described when N is 9.

The signal processors 110-1 to 110-9 are disposed between the input terminal 101 and the output terminal 102. The configuration of signal processors 110-1 to 110-9 is identical, and therefore, reference numerals are assigned as delay devices 111 and 112, the adder 113, and the amplifier 114 included in the signal processor 110-1 in FIG. 2A, but the same is true for the signal processors 110-2 to 110-9.

An input terminal of the delay device 111 of the signal processor 110-9 and a first input terminal of the adders 113 of the signal processor 110-9 are connected to the input terminal 101. As for each of the signal processors 110-1 to 110-8, an input terminal of the delay device 111 is connected to a first input terminal of the adder 113 and an output terminal of the delay device 111 of the adjacent signal processor 110 (left-nearest) with one larger order number. An output terminal of the delay device 111 of the signal processor 110-1 is connected to an input terminal of the amplifier 120.

An input terminal of the delay device 112 of the signal processor 110-1 is connected to the output terminal 102 and an output terminal of the amplifier 140. Input terminals of the delay devices 112 of the signal processors 110-2 to 110-9 are connected to output terminals of the delay devices 112 of the adjacent (right-nearest) signal processors 110 with one lower order. Furthermore, in each of the signal processors 110-1 to 110-8, an output terminal of the delay device 112 is connected to a second input terminal of the adder 113 of the signal processor 110 and the input terminal of the delay device 112 of the adjacent (left-nearest) signal processor 110 with one larger order number. The output terminal of the delay device 112 of the signal processor 110-9 is connected to a second input terminal of the adder 113 of the signal processor 110-9. In each of the signal processors 110, an output terminal of the adder 113 is connected to an input terminal of amplifier 114. The adder 113 outputs a difference obtained by subtracting a signal input to the second input terminal (lower input terminal) from a signal input to the first input terminal on an upper side (upper input terminal).

An output terminal of the amplifier 114 of the signal processor 110-1 and an output terminal of the adder 130-2 are connected to first and second input terminals of the adder 130-1, respectively. These connection relationships are similar in that the output terminals of the amplifiers 114 of the signal processors 110-2 to 110-7 are connected to the first input terminals of the adders 130-2 to 130-7, respectively, and the output terminals of the adders 130-3 to 130-8 are connected to the second input terminals of the adders 130-2 to 130-7, respectively. An output terminal of the amplifier 114 of the signal processor 110-8 and an output terminal of the amplifier 114 of the signal processor 110-9 are connected to first and second input terminals of the adder 130-8, respectively. Furthermore, an output terminal of the amplifier 120 and an output terminal of the adder 130-1 are connected to first and second input terminals of the adder 130-0, respectively. An output terminal of the adder 130-0 is connected to an input terminal of the amplifier 140. Each of the adders 130-0 to 130-8 outputs a sum obtained by adding the signals input to the first and second input terminals.

The amplifier 140 is disposed to correct a filter output when a coefficient of a filter coefficient a0 described below is not 0 (zero) or 1. An amplification factor of the amplifier 140 is 1/a0. An output terminal of the amplifier 140 is connected to the output terminal 102.

It is assumed that, in FIG. 2A, amplification factors of the ten amplifiers, that is, the amplifier 120 and the amplifiers 114 of the signal processors 110-1 to 110-9 are determined to have filter coefficients a0 to a9. In the following, a filter coefficient in an Nth-order IIR-type all-pass filter 100 is denoted as ai. An index i of the filter coefficient ai is one of 0 to N (i=0 to N).

FIG. 2B is a diagram illustrating an example of another configuration of the IIR-type all-pass filter 100 according to the embodiment. The IIR-type all-pass filter 100 illustrated in FIG. 2B has the following configuration. That is, the signal processor 110-1 and the adder 130-1 of the IIR-type all-pass filter 100 illustrated in FIG. 2A are removed, the amplification factor of the amplifier 120 is changed to a1, and furthermore, an amplification factor of the amplifier 140 is changed to 1/a1. In order to avoid infinite divergence of the amplification factor (1/a0) of the amplifier 140, when the filter coefficient a0 in the IIR-type all-pass filter 100 illustrated in FIG. 2A is zero, the IIR-type all-pass filter 100 illustrated in FIG. 2B has a configuration in which the signal processor 110-1 and the adder 130-1 associated with the filter coefficient a0 are removed from the IIR-type all-pass filter 100 of FIG. 2A and the amplification factor of the amplifier 120 is changed to a1, and furthermore, the amplification factor of the amplifier 140 is changed to 1/a1.

Here, when any of the filter coefficients a1 to a9 in FIG. 2A may be set to zero, the amplifiers 114 and the adders 113 of the signal processors 110-1 to 110-9 may be removed, and therefore, reduction in size and power consumption of the IIR-type all-pass filter 100 may be realized. Here, when any of the filter coefficients a2 to a9 in FIG. 2B may be set to zero, the amplifiers 114 and the adders 113 of the signal processors 110-2 to 110-9 may be removed, and therefore, reduction in size and power consumption of the IIR-type all-pass filter 100 may be realized.

### <Frequency Characteristic of IIR-Type All-Pass Filter 100 (M=N−3)>

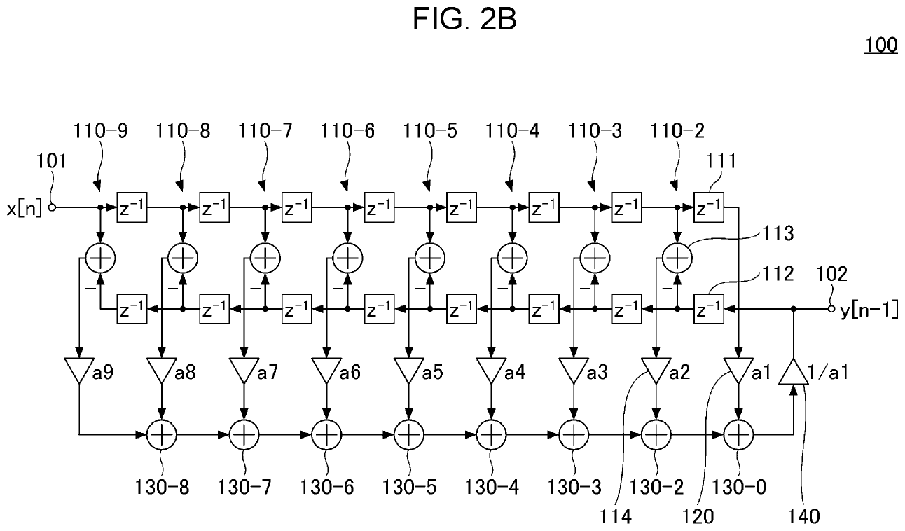

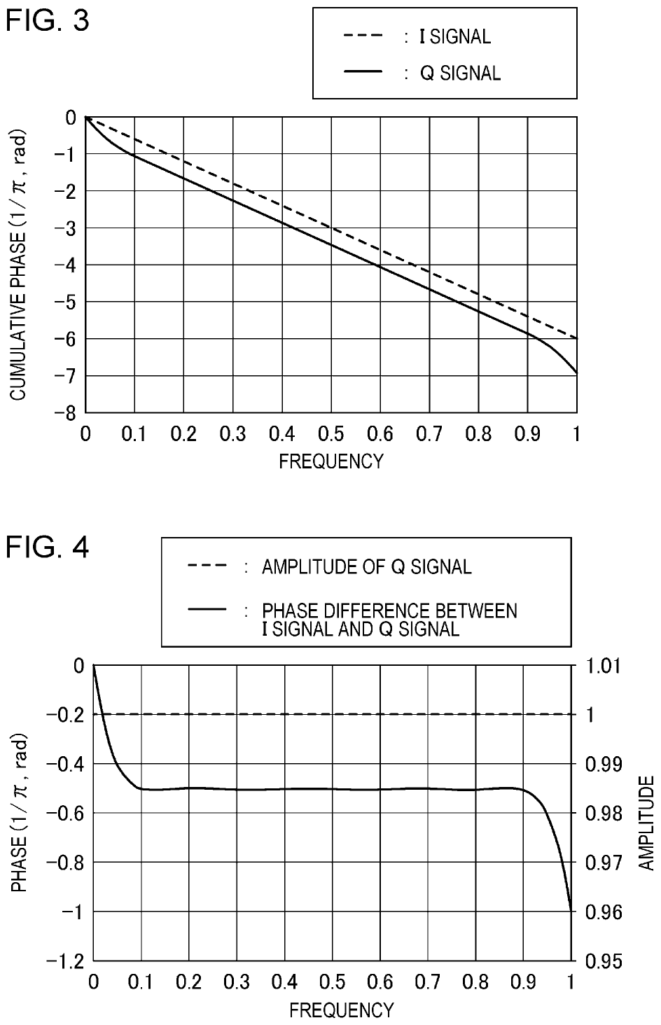

FIG. 3 is a graph of an example of a frequency characteristic of a cumulative phase of the IIR-type all-pass filter 100. In FIG. 3, an axis of abscissae indicates a frequency and an axis of ordinates indicates a cumulative phase. A frequency on the axis of abscissae is normalized by the Nyquist frequency, which is ½ the sampling frequency, and has no units. The cumulative phase on the axis of ordinates represents the number of 1/π radians (rad). A value of −6 on the axis of ordinates indicates that a phase is shifted by −6π in a direction of delay with respect to 0. In FIG. 3, the I signal is indicated by a dashed line and the Q signal is indicated by a solid line.

The I signal output from the digital signal delay circuit 8 (refer to FIG. 1) is characterized by a −6π shift while the frequency changes from 0 to 1. The Q signal is delayed in phase by 90 degrees with respect to the I signal in a frequency band of 0.1 to 0.9 and has a characteristic of a linear change with respect to increase in frequency (x/2 phase shift characteristic). In the following, the number of group delays (group delay count) M is defined by an inclination of the frequency characteristic of the cumulative phase illustrated in FIG. 3, and is given as a sign-inverted value of a resultant obtained by dividing a change amount of the cumulative phase by a width of the frequency. For the I signal, the cumulative phase linearly changes by −6 while the frequency changes from 0 to 1, and therefore, the group delay count is 6. For the Q signal, the cumulative phase linearly changes by −4.8 (from −1.2 to −6) while the frequency changes from 0.1 to 0.9, and therefore, the group delay count is 6 simultaneously with the I signal. The IIR-type all-pass filter 100 with the frequency characteristic illustrated in FIG. 3 has an order N of 9 and a group delay count M of 6 (M=6). In other words, the IIR-type all-pass filter 100 with the frequency characteristic illustrated in FIG. 3 is an IIR-type all-pass filter with M of N−3. In designing the IIR-type all-pass filter 100, a width of a frequency band over which the Q signal linearly varies with respect to a change in frequency is referred to as a design bandwidth, a lower limit of the design bandwidth as a frequency low limit, and a higher limit of the design bandwidth as a frequency high limit.

### <Phase Difference Between 1 and Q Signals and Frequency Characteristic of Amplitude of Q Signal>

FIG. 4 is a graph of an example of a frequency characteristic of a phase difference between the I and Q signals and an amplitude of the Q signal. In FIG. 4, an axis of abscissae represents a normalized frequency, and a left axis of ordinates represents the phase difference between the I and Q signals in 1/π radians (rad). A right axis of ordinates represents an amplitude of the Q signal. In FIG. 4, a phase difference between the I and Q signals is indicated by a solid line and an amplitude of the Q signal is indicated by a dashed line.

As illustrated in FIG. 4, in the frequency band of 0.1 to 0.9, the phase difference between the I and Q signals is approximately 0.5 (π/2=90 degrees), and the amplitude of the Q signal is 1.

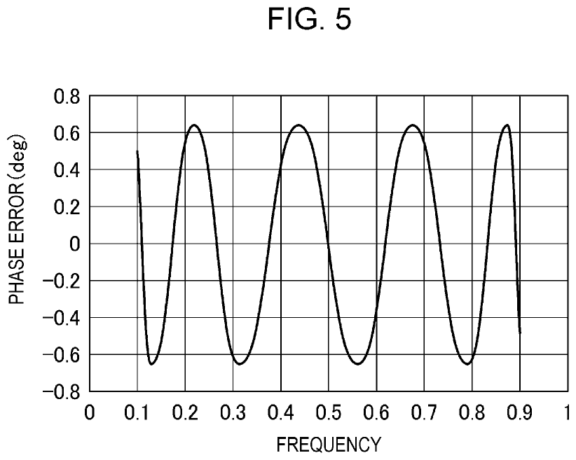

FIG. 5 is a graph of an example of the frequency characteristic of a phase error of the Q signal. In FIG. 5, an axis of abscissae represents a normalized frequency, and an axis of ordinates represents a phase error of the Q signal in degrees. The phase error of the Q signal is an error with respect to −90 degrees. As illustrated in FIG. 5, the phase error of the Q signal for a change in frequency is +0.64 degrees, confirming that the characteristic of equal ripple with equal upper and lower amplitude is obtained. An indication of whether the phase error is a preferable value is less than 1 degree in absolute value as an example.

### Combination of Order N and Group Delay Count M

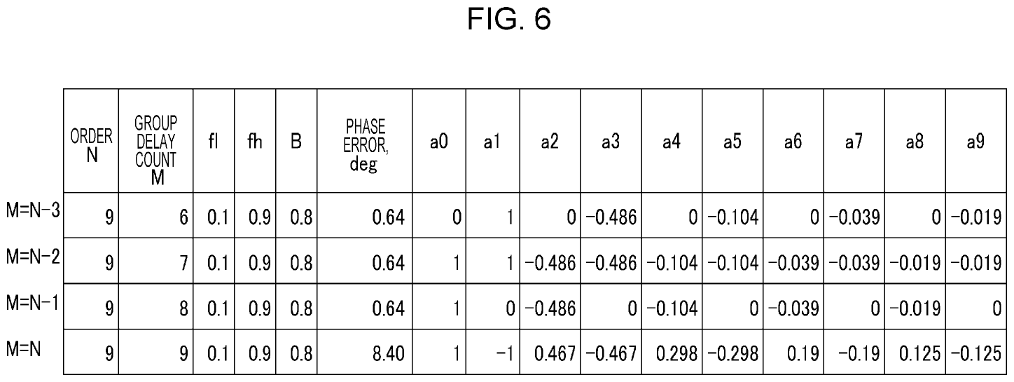

FIG. 6 is a table of an example of the relationship among a combination of the order N and the group delay count M, a frequency low limit fl, a frequency high limit fh, a design bandwidth B, a phase error, and the filter coefficients a0 to a9. Here, the frequency is normalized by the Nyquist frequency, which is ½ of the sampling frequency. Since the frequency low limit fl and the frequency high limit fh are symmetrically set around ½ of the Nyquist frequency, there is a relationship “fl+fh=1” for the frequency low limit fl and the frequency high limit fh.

In the table in FIG. 6, calculation results of phase errors and filter coefficients a0 to a9 are illustrated which are obtained for four combinations of order N and group delay count M, that is, a combination of N=9 and M=N−3=6, a combination of N=9 and M=N−2=7, a combination of N=9 and M=N−1=8, and a combination of N=9 and M=N=9, where the frequency low limit fl is 0.1, the frequency high limit fh is 0.9, and the design bandwidth B is 0.8. Here, all the filter coefficients a0 to a9 which are normalized so that a maximum value of the filter coefficients a0 to a9 is 1 are illustrated. The filter coefficient ai may also take a negative value. Here, the maximum value of the filter coefficients a0 to a9 is set to 1. The phase error is represented in absolute value.

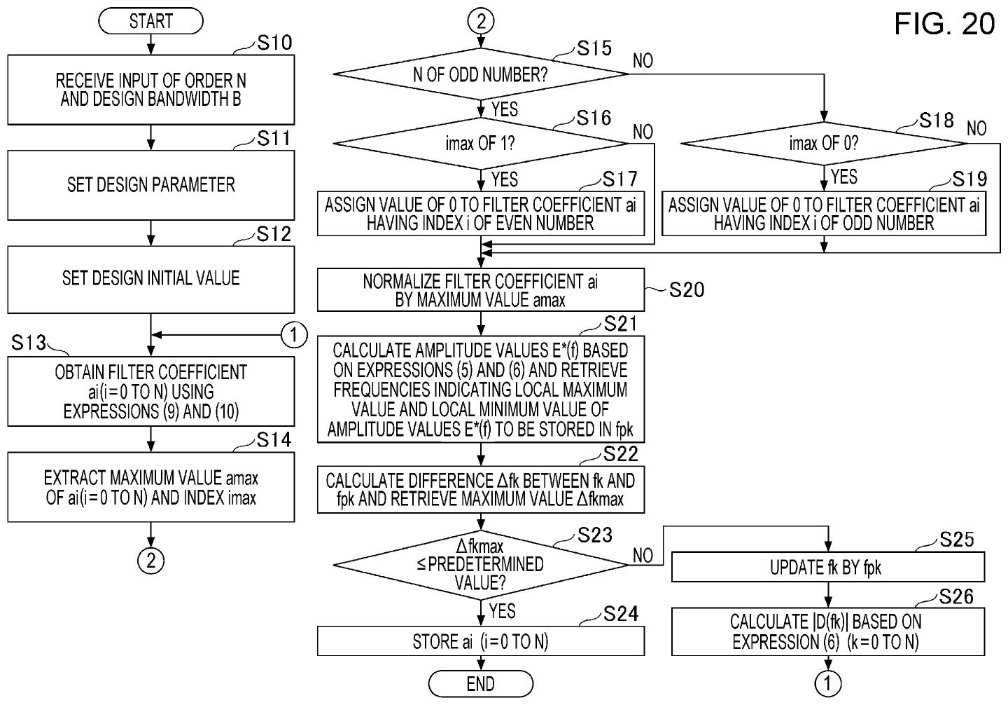

When M=N−3=6, the phase error is a preferable value of 0.64 degrees, and among the filter coefficients a0 to a9, the filter coefficients ai with even-numbered indices i are zero. Specifically, the filter coefficients a0, a2, a4, a6, and a8 are zero. Here, the filter coefficients ai illustrated in FIG. 6 have values where significant figures are to the third decimal place, that is, rounded off to the third decimal place. These values are obtained by a process described below with reference to FIG. 20.

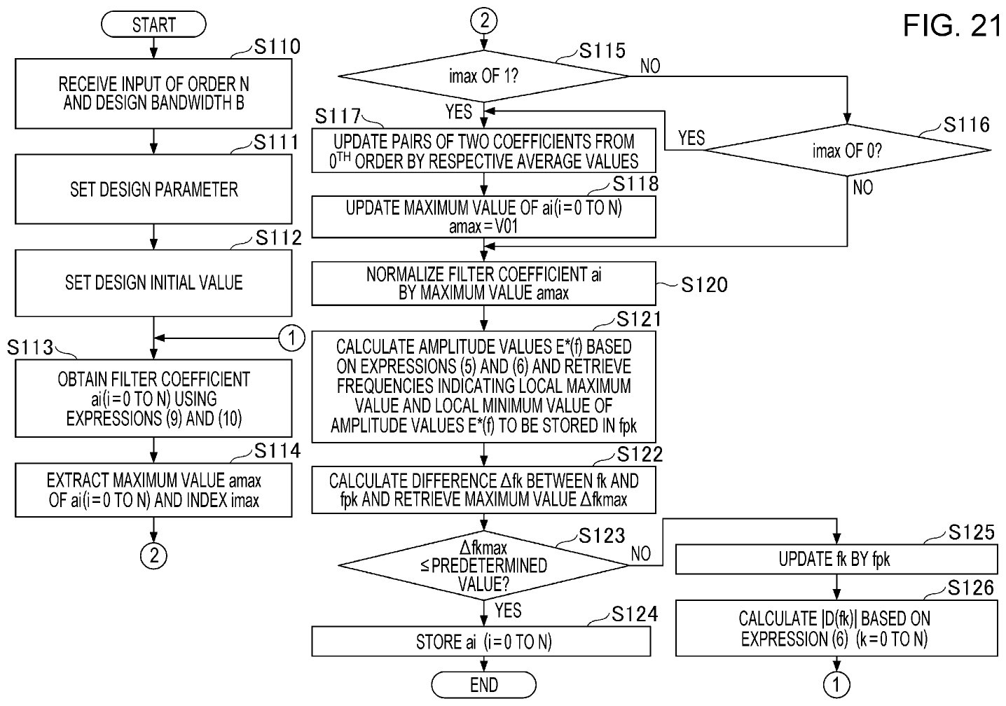

When M=N−2=7, the phase error is a preferable value of 0.64 degrees, and when the filter coefficients a0 to a9 is divided into pairs of adjacent two filter coefficients ai from the index i of 0, the adjacent two filter coefficients ai in each of the pairs have the same value. Specifically, the filter coefficients a0 and a1 are both 1, the filter coefficients a2 and a3 are both −0.486, the filter coefficients a4 and a5 are both −0.104, the filter coefficients a6 and a7 are both −0.039, and filter coefficients a8 and a9 are both −0.019. The reason that the adjacent two filter coefficients ai in each of the pairs constituted from the index i of 0 have the same value is that the filter coefficients ai of the adjacent two indices i from 0 have an average value of the two filter coefficients ai. These values are obtained by a process described below with reference to FIG. 21.

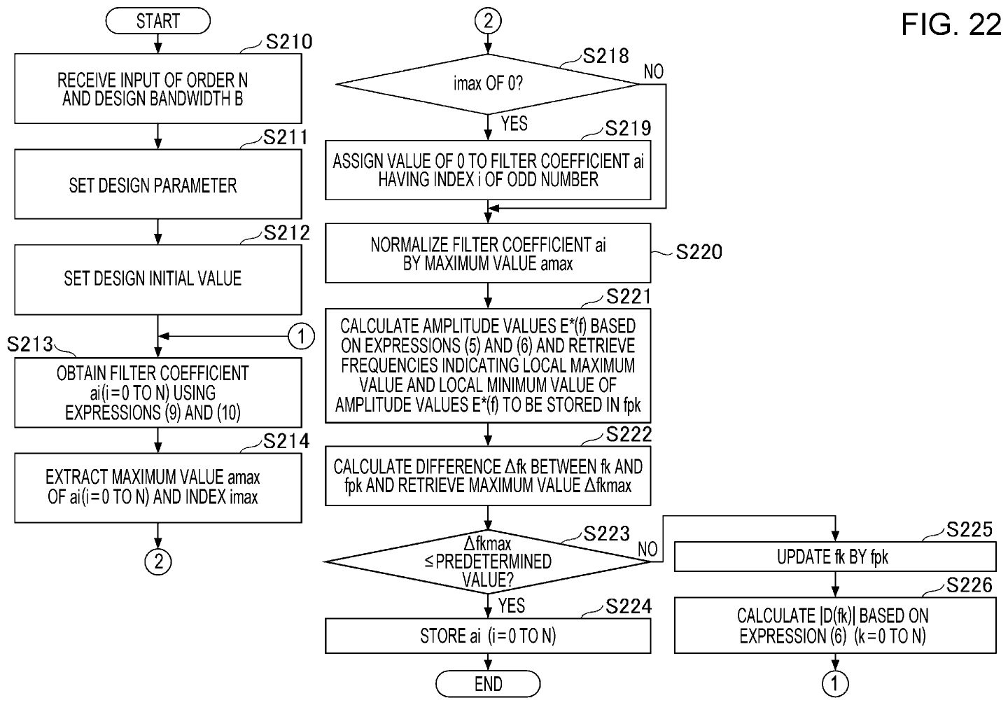

Furthermore, when M=N−1=8, the phase error is a preferable value of 0.64 degrees, and among the filter coefficients a0 to a9, the filter coefficients ai with odd-numbered indices i are zero. Specifically, the filter coefficients a1, a3, a5, a7, and a9 are zero. Here, the filter coefficients ai illustrated in FIG. 6 have values where significant figures are to the third decimal place, that is, rounded off to the third decimal place. These values are obtained by a process described below with reference to FIG. 22.

When M=N=9, the phase error is 8.40 degrees which is not a preferable value. Therefore, as for the combinations of the order N and the group delay count M in the cases of M=N−3, M=N−2, and M=N−1, the phase errors are preferable, and therefore, these combinations may be applied to the IIR-type all-pass filter 100, and whereas, the combination of the order N of M=N and the group delay count M is not available. Note that the method for obtaining a filter coefficient for M=N=9 will be described at an end of the description with reference to FIG. 21.

For the combination of order N and group delay count M in the case of M=N−3, the filter coefficients ai with the even-numbered indices i, among the filter coefficients a0 to a9, are zero, and therefore, approximately half (four) of the nine amplifiers in total, that is, the amplifiers 114 of the signal processors 110-2 to 110-9 and the amplifier 120 illustrated in FIG. 2B and the surrounding components may be removed.

Similarly, for the combination of order N and group delay count M in the case of M=N−1, the filter coefficients ai with the odd-numbered indices i, among the filter coefficients a0 to a9, are zero, and therefore, half (five) of the ten amplifiers in total, that is, the amplifiers 114 of the signal processors 110-1 to 110-9 and the amplifier 120 illustrated in FIG. 2A and the surrounding components may be removed.

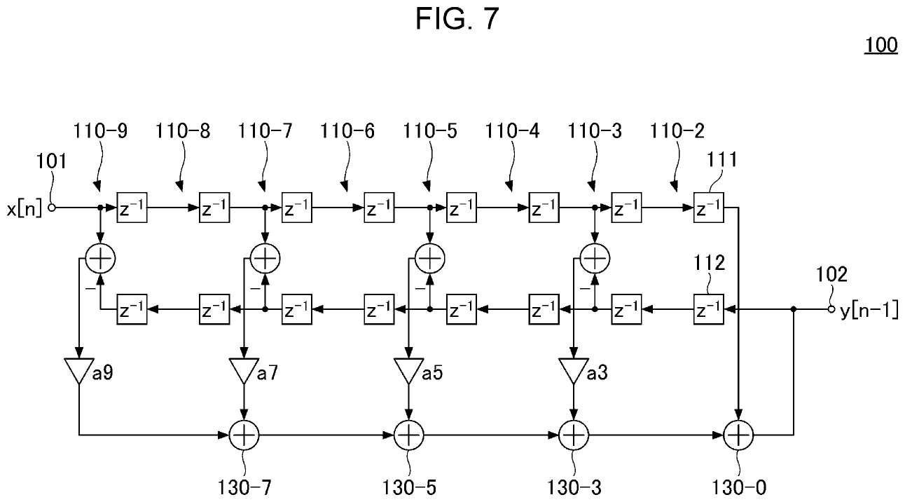

Furthermore, for the combination of order N and group delay count M in the case of M=N−2, the single amplifier is used for the two amplifiers for the pair of filter coefficients ai starting from the index i of 0 (that is, a common amplifier is used), and therefore, half (five) of the ten amplifiers in total, that is, the amplifiers 114 of the signal processors 110-1 to 110-9 and the amplifier 120 illustrated in FIG. 2A and the surrounding components may be removed. More specifically, the amplifier 120 and the amplifier 114 of the signal processor 110-1 are integrated as one common amplifier, the amplifiers 114 of the signal processors 110-2 and 110-3 are integrated as one common amplifier, the amplifiers 114 of the signal processors 110-4 and 110-5 are integrated as one common amplifier, the amplifiers 114 of the signal processors 110-6 and 110-7 are integrated as one common amplifier, and the amplifiers 114 of the signal processors 110-8 and 110-9 are integrated as one common amplifier, so that the number of amplifiers may be reduced to half. In addition, by reducing the number of amplifiers, specifically, the components in front and rear of the amplifiers may also be reduced. Specific examples are illustrated in FIGS. 7 to 9.

<IIR-Type All-Pass Filter 100 with Simplified Circuit Configuration (M=N−3)>

FIG. 7 is a diagram illustrating an IIR-type all-pass filter 100 with a simplified circuit configuration. In FIG. 7, a configuration of the IIR-type all-pass filter 100 with M=N−3 is illustrated. When N=9 and M=N−3=6, the IIR-type all-pass filter 100 illustrated in FIG. 2B is used since the filter coefficient a0 is zero, and the amplifiers 114 (a2, a4, a6, and a8) of the signal processors 110-2, 110-4, 110-6, and 110-8 may be removed with respective paths since the filter coefficients a2, a4, a6, and a8 are zero. Furthermore, since the amplifiers 114 (a2, a4, a6, and a8) of the signal processors 110-2, 110-4, 110-6, and 110-8 are removed with the respective paths, the adders 113 of the signal processors 110-2, 110-4, 110-6, and 110-8 may be removed with respective paths.

Furthermore, since the amplifiers 114 (a2, a4, a6, and a8) in the signal processors 110-2, 110-4, 110-6, and 110-8 are removed, the adders 130-2, 130-4, 130-6, and 130-8 may be removed. Since the amplifier 120 has a filter coefficient a1 of 1 (a1=1), the amplifier 120 is removed and the output terminal of the delay device 111 of the signal processor 110-2 is connected to the first input terminal of the adder 130-0. Furthermore, the amplifier 140 (1/a1) is removed and the output terminal of the adder 130-0 is connected to the input terminal of the delay device 112 of the signal processor 110-2 and the output terminal 102.

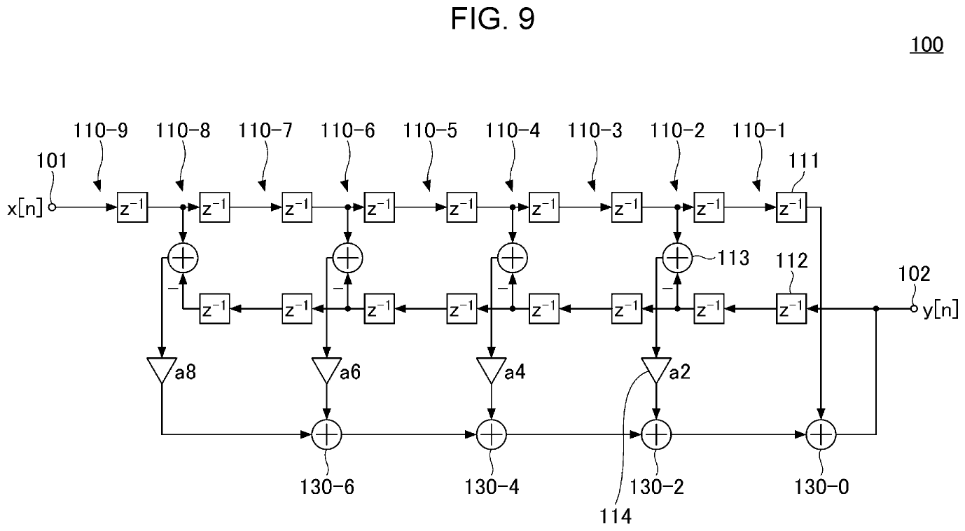

As a result, the IIR-type all-pass filter 100 with the circuit configuration illustrated in FIG. 7 may be designed. The IIR-type all-pass filter 100 illustrated in FIG. 7 with N=9 and M=N−3=6 has a much simplified circuit configuration compared to the IIR-type all-pass filter 100 illustrated in FIG. 2B, and therefore, reduction in size, lower cost, and lower power consumption may be realized. The IIR-type all-pass filter 100 with N=9 and M=N−3=6 illustrated in FIG. 7 has fewer components than the IIR-type all-pass filter 100 with N=9 and M=N−1=8, which will be described below with reference to FIG. 9.

<IIR-Type All-Pass Filter with Simplified Circuit Configuration 100 (M=N−2)>

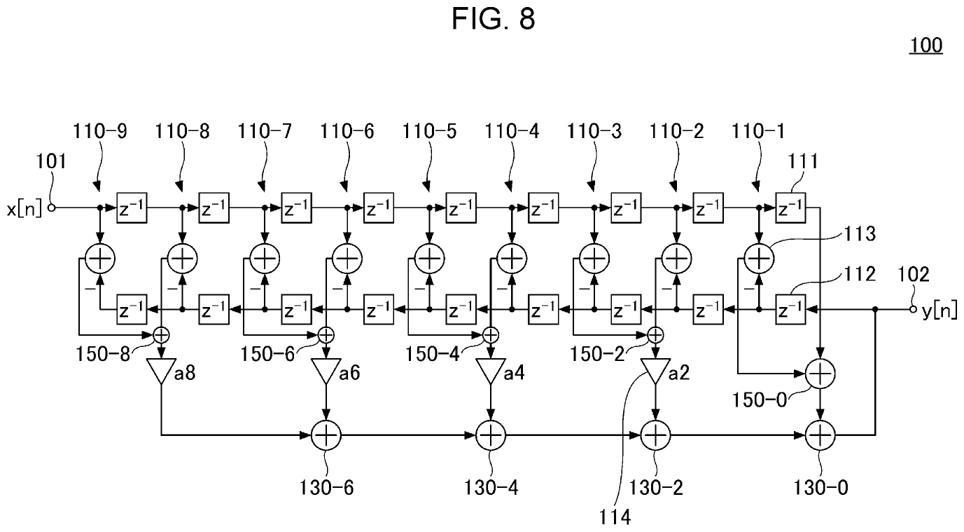

FIG. 8 is a diagram illustrating an IIR-type all-pass filter 100 with a simplified circuit configuration. In FIG. 8, a configuration of the IIR-type all-pass filter 100 with M=N−2 is illustrated. When N=9 and M=N−2=7, the filter coefficients a0 and a1 are both 1, and therefore, the amplifier 120 and the amplifier 114 of the signal processor 110-1 are removed, and the output terminal of the delay device 111 of the signal processor 110-1 and the output terminal of the adder 113 are connected to the first input terminal of the adder 130-0 via a newly added adder 150-0.

Furthermore, the filter coefficients a2 and a3 have the same value, the filter coefficients a4 and a5 have the same value, the filter coefficients a6 and a7 have the same value, and the filter coefficients a8 and a9 have the same value. Therefore, the amplifiers 114 (a3, a5, a7, and a9) of the signal processors 110-3, 110-5, 110-7, and 110-9 are removed, the output terminals of the adders 113 of the signal processors 110-3, 110-5, 110-7, and 110-9 are connected through newly added adders 150-2, 150-4, 150-6 and 150-8 to the input terminals of the amplifiers 114 (a2, a4, a6, and a8) of the signal processors 110-2, 110-4, 110-6, 110-8.

In addition, since the amplifiers 114 (a1, a3, a5, a7, and a9) of the signal processors 110-1, 110-3, 110-5, 110-7, and 110-9 are removed, the adders 130-1, 130-3, 130-5, 130-7, and 130-8 may be removed. Since the filter coefficient a0 is 1, the amplifier 140 with an amplification factor of 1/a0 is removed and the output terminal of the adder 130-0 is connected to the output terminal 102.

As a result, the IIR-type all-pass filter 100 with the circuit configuration illustrated in FIG. 8 may be designed. Although the IIR-type all-pass filter 100 illustrated in FIG. 8 with N=9 and M=N−2=7 has a circuit configuration slightly larger than the IIR-type all-pass filter 100 illustrated in FIG. 7, when compared to the IIR-type all-pass filter 100 illustrated in FIG. 2A, the circuit configuration is sufficiently reduced and reduction in size, lower cost, and lower power consumption may be realized.

<IIR-Type All-Pass Filter with Simplified Circuit Configuration 100 (M=N−1)>

FIG. 9 is a diagram illustrating an IIR-type all-pass filter 100 with a simplified circuit configuration. In FIG. 9, a configuration of the IIR-type all-pass filter 100 with M=N−1 is illustrated. When N=9 and M=N−1=8, the filter coefficients a1, a3, a5, a7, and a9 are zero, and therefore, the amplifiers 114 (a1, a3, a5, a7, and a9) of the signal processors 110-1, 110-3, 110-5, 110-7, and 110-9 may be removed with respective paths. Furthermore, since the amplifiers 114 (a1, a3, a5, a7, a9) of the signal processors 110-1, 110-3, 110-5, 110-7, 110-9 are removed with the respective paths, the adders 113 of the signal processors 110-1, 110-3, 110-5, 110-7, and 110-9 may be removed with respective paths. Furthermore, since the adder 113 of the signal processor 110-9 is removed, the delay device 112 of the signal processor 110-9 may also be removed.

Furthermore, since the amplifiers 114 (a1, a3, a5, and a7) of the signal processors 110-1, 110-3, 110-5, and 110-7 are removed, the adders 130-1, 130-3, 130-5, and 130-7 may be removed. Furthermore, since the amplifier 114 (a9) of the signal processor 110-9 is removed, the adder 130-8 may be removed. Since the filter coefficient a0 is 1, the amplifier 120 and the amplifier 140 with an amplification factor of 1/a0 are removed, the output terminal of the delay device 111 of the signal processor 110-1 is connected to the first input terminal of the adder 130-0, and the output terminal of the adder 130-0 is connected to the output terminal 102.

As a result, the IIR-type all-pass filter 100 with the circuit configuration illustrated in FIG. 9 may be designed. The IIR-type all-pass filter 100 illustrated in FIG. 9 with N=9 and M=N−1=8 has a much simplified circuit configuration compared to the IIR-type all-pass filter 100 illustrated in FIG. 2A, and therefore, reduction in size, lower cost, and lower power consumption may be realized.

Next, the frequency characteristic of the IIR-type all-pass filter 100 with M=N−2 and M=N−1 will be described. Note that the frequency characteristic of the IIR-type all-pass filter 100 with M=N−3 is illustrated in FIGS. 3 to 5.

### <Frequency Characteristic of IIR-Type All-Pass Filter 100 (M=N−2)>

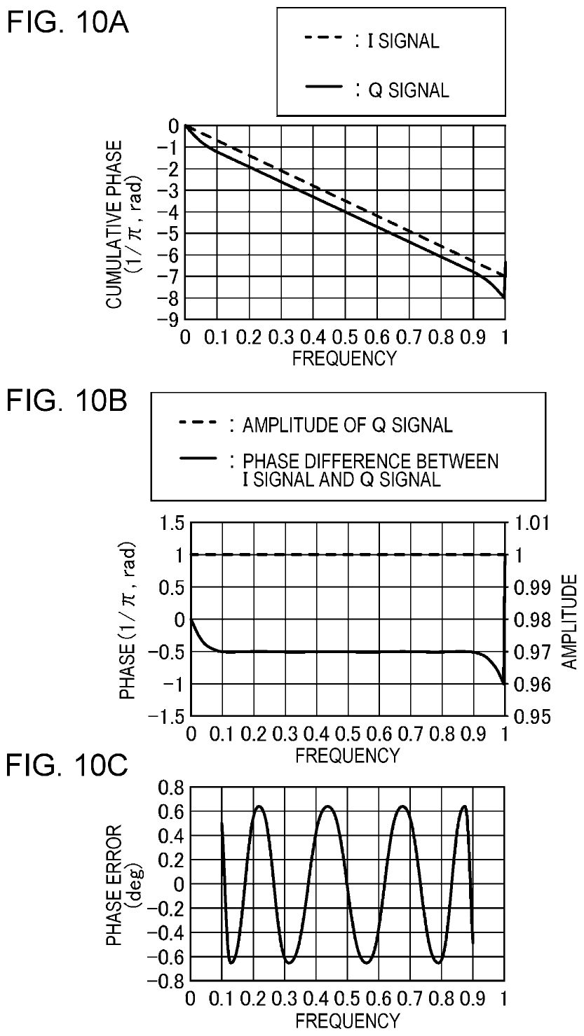

FIGS. 10A to 10C are graphs of examples of the frequency characteristic of the IIR-type all-pass filter 100 with the order N of 9 and M of N−2. In FIG. 10A, an axis of abscissae indicates a frequency and an axis of ordinates indicates a cumulative phase. The frequency on the axis of abscissae is a normalized frequency, and therefore, has no units. The cumulative phase on the axis of ordinates represents the number of 1/π radians (rad). In FIG. 10A, the I signal is indicated by a dashed line and the Q signal is indicated by a solid line.

The I signal output from the digital signal delay circuit 8 (refer to FIG. 1) is characterized by a −7π shift while the frequency changes from 0 to 1. The Q signal is delayed in phase by 90 degrees with respect to the I signal in a frequency band of 0.1 to 0.9 and has a characteristic of a linear change with respect to increase in frequency (x/2 phase shift characteristic). The IIR-type all-pass filter 100 with the frequency characteristic illustrated in FIG. 10A has the order N of 9 and M is N−2, and therefore, a group delay count M is 7 (M=7). In fact, the cumulative phase linearly changes by −5.6 (from −1.2 to −6.8) while the frequency changes from 0.1 to 0.9, and therefore, the group delay count is 7 simultaneously with the I signal.

Furthermore, FIG. 10B is a graph of an example of a frequency characteristic of a phase difference between the I and Q signals. In FIG. 10B, an axis of abscissae represents a normalized frequency, and a left axis of ordinates represents a phase difference between the I and Q signals in 1/π radians (rad). A right axis of ordinates represents an amplitude of the Q signal. In FIG. 10B, the phase difference between the I and Q signals is indicated by a solid line and the amplitude of the Q signal is indicated by a dashed line.

As illustrated in FIG. 10B, in the frequency band of 0.1 to 0.9, the phase difference between the I and Q signals is approximately 0.5 (π/2=90 degrees), and the amplitude of the Q signal is 1.

FIG. 10C is a graph of an example of the frequency characteristic of a phase error of the Q signal. In FIG. 10C, an axis of abscissae represents a normalized frequency, and an axis of ordinates represents a phase error of the Q signal in degrees. The phase error of the Q signal is an error with respect to −90 degrees. As illustrated in FIG. 10C, the phase error of the Q signal for the change in frequency is +0.64 degrees, confirming that the characteristic of preferable equal ripple with equal upper and lower amplitude is obtained.

### Frequency Characteristic of IIR-Type All-Pass Filter 100 (M=N−1)

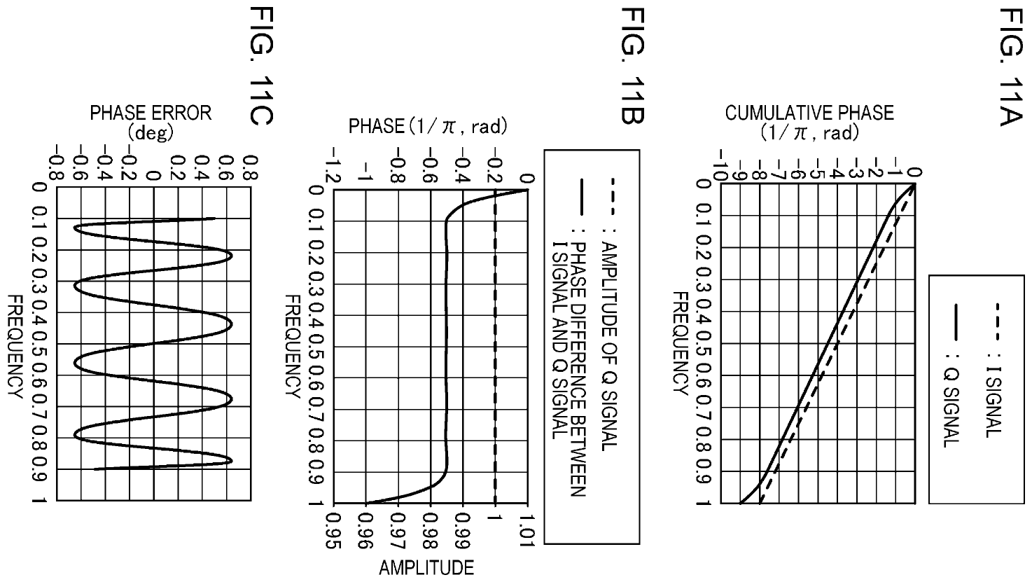

FIGS. 11A to 11C are graphs of examples of the frequency characteristic of the IIR-type all-pass filter 100 with the order N of 9 and M of N−1. In FIG. 11A, an axis of abscissae indicates a frequency and an axis of ordinates indicates a cumulative phase. The frequency on the axis of abscissae is a normalized frequency, and therefore, has no units. The cumulative phase on the axis of ordinates represents the number of 1/π radians (rad). In FIG. 11A, the I signal is indicated by a dashed line and the Q signal is indicated by a solid line.

The I signal output from the digital signal delay circuit 8 (refer to FIG. 1) is characterized by a −8π shift while the frequency changes from 0 to 1. The Q signal is delayed in phase by 90 degrees with respect to the I signal in a frequency band of 0.1 to 0.9 and has a characteristic of a linear change with respect to increase in frequency (x/2 phase shift characteristic). The IIR-type all-pass filter 100 with the frequency characteristic illustrated in FIG. 11A has an order N of 9 and M is N−1, and therefore, a group delay count M is 8 (M=8). In fact, the cumulative phase linearly changes by −6.4 (from −1.3 to −7.7) while the frequency changes from 0.1 to 0.9, and therefore, the group delay count is 8 simultaneously with the I signal.

Furthermore, FIG. 11B is a graph of an example of a frequency characteristic of a phase difference between the I and Q signals. In FIG. 11B, an axis of abscissae represents a normalized frequency, and a left axis of ordinates represents a phase difference between the I and Q signals in 1/π radians (rad). A right axis of ordinates represents an amplitude of the Q signal. In FIG. 11B, the phase difference between the I and Q signals is indicated by a solid line and the amplitude of the Q signal is indicated by a dashed line.

As illustrated in FIG. 11B, in the frequency band of 0.1 to 0.9, the phase difference between the I and Q signals is approximately 0.5 (π/2=90 degrees), and the amplitude of the Q signal is 1.

FIG. 11C is a graph of an example of the frequency characteristic of a phase error of the Q signal. In FIG. 11C, an axis of abscissae represents a normalized frequency, and an axis of ordinates represents a phase error of the Q signal in degrees. The phase error of the Q signal is an error with respect to −90 degrees. As illustrated in FIG. 11C, the phase error of the Q signal for the change in frequency is +0.64 degrees, confirming that the characteristic of preferable equal ripple with equal upper and lower amplitude is obtained.

### <Configuration of IIR-Type All-Pass Filter 100 (N=10)>

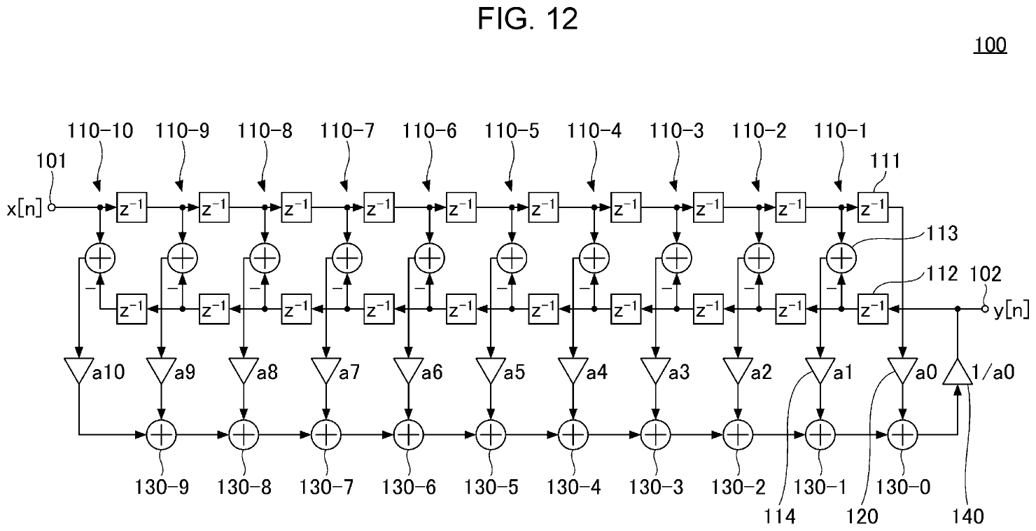

FIG. 12 is a diagram illustrating an example of a configuration of an IIR-type all-pass filter 100 (N=10) according to the embodiment. The IIR-type all-pass filter 100 illustrated in FIG. 12 is a filter with the order N of 10.

The IIR-type all-pass filter 100 with the order N of 10 has the configuration of the IIR-type all-pass filter 100 with the order N of 9 illustrated in FIG. 2A, with an addition of a signal processor 110-10 and an adder 130-9. Specifically, the IIR-type all-pass filter 100 with the order N of 10 includes 10 signal processors 110-1 to 110-10, an amplifier 120, 10 adders 130-0 to 130-9, and an amplifier 140 which are disposed between the input terminal 101 and the output terminal 102. Filter coefficients of the amplifiers 114 of the signal processors 110-1 to 110-10 are a0 to a10.

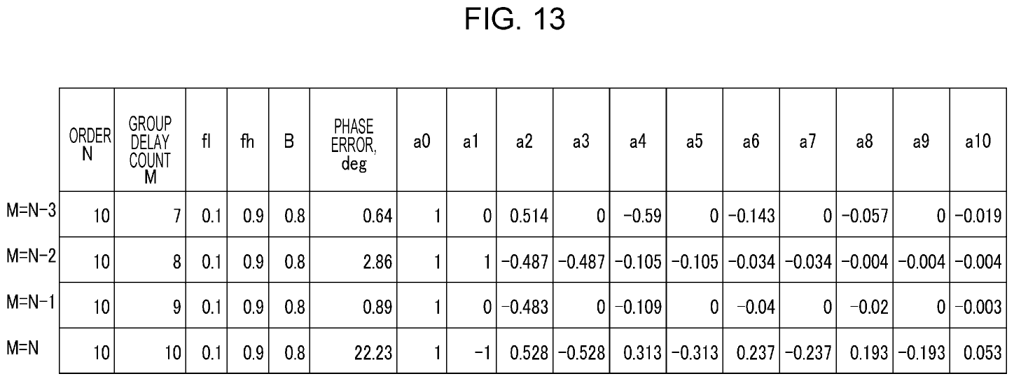

FIG. 13 is a table of an example of the relationship among a combination of the order N and the group delay count M, a frequency low limit fl, a frequency high limit fh, a design bandwidth B, a phase error, and the filter coefficients a0 to a9.

In the table in FIG. 13, calculation results of phase errors and the filter coefficients a0 to a10 are illustrated which are obtained for four combinations of an order N and a group delay count M, that is, a combination of N=10 and M=N−3=7, a combination of N=10 and M=N−2=8, a combination of N=10 and M=N−1=9, and a combination of N=10 and M=N=10, where the frequency low limit fl is 0.1, the frequency high limit fh is 0.9, and the design bandwidth B is 0.8. Here, all the filter coefficients a0 to a 10 which are normalized so that a maximum value of the filter coefficients a0 to a10 is 1 are illustrated. The filter coefficient ai may also take a negative value. Here, the maximum value of the filter coefficients a0 to a10 is set to 1. The phase error is represented in absolute value.

When M=N−3=7, the phase error is a preferable value of 0.64 degrees, and among the filter coefficients a0 to a10, the filter coefficients ai with odd-numbered indices i are zero. Specifically, the filter coefficients a1, a3, a5, a7, and a9 are zero. Here, the filter coefficients ai illustrated in FIG. 13 are values where significant figures are to the third decimal place, that is, rounded off to the third decimal place. These values are obtained by a process described below with reference to FIG. 20.

When M=N−2=8, the phase error is a preferable value of 2.86 degrees which is slightly high value, and when the filter coefficients a0 to a10 are divided into pairs of adjacent two filter coefficients ai from the index i of 0, the adjacent two filter coefficients ai in each of the pairs have the same value. Specifically, the filter coefficients a0 and a1 are both 1, the filter coefficients a2 and a3 are both −0.487, the filter coefficients a4 and a5 are both −0.105, the filter coefficients a6 and a7 are both −0.034, and filter coefficients a8 and a9 are both −0.004. The reason that the adjacent two filter coefficients ai in each of the pairs constituted from the index i of 0 have the same value is that the filter coefficients ai of the adjacent two indices i from 0 have an average value of the two filter coefficients ai. Note that the filter coefficient a10 is also −0.004, but a value of a fourth decimal place is different from those of the filter coefficients a8 and a9. These values are obtained by a process described below with reference to FIG. 21.

Furthermore, when M=N−1=9, the phase error is a preferable value of 0.89 degrees, and among the filter coefficients a0 to a10, the filter coefficients ai with odd-numbered indices i are zero. Specifically, the filter coefficients a1, a3, a5, a7, and a9 are zero. Here, the filter coefficients ai illustrated in FIG. 13 are values where significant figures are to the third decimal place, that is, rounded off to the third decimal place. These values are obtained by a process described below with reference to FIG. 22.

When M=N=10, the phase error is 22.23 degrees which is not a preferable value. Therefore, when N is 10, as for the combinations of the order N and the group delay count M in the cases of M=N−3, M=N−2, and M=N−1, the phase errors are preferable, and therefore, these combinations may be applied to the IIR-type all-pass filter 100, and whereas, the combination of the order N of M=N and the group delay count M is not available. Note that the method for obtaining a filter coefficient for M=N=10 will be described at an end of the description with reference to FIG. 21.

Furthermore, for the combination of order N and group delay count M in the case of M=N−3, the filter coefficients ai with the odd-numbered indices i, among the filter coefficients a0 to a10, are zero, and therefore, approximately half (five) of the eleven amplifiers in total, that is, the amplifiers 114 of the signal processors 110-1 to 110-10 and the amplifier 120 illustrated in FIG. 12 and the surrounding components may be removed.

Similarly, for the combination of order N and group delay count M in the case of M=N−1, the filter coefficients ai with the odd-numbered indices i, among the filter coefficients a0 to a10, are zero, and therefore, approximately half (five) of the eleven amplifiers in total, that is, the amplifiers 114 of the signal processors 110-1 to 110-10 and the amplifier 120 illustrated in FIG. 12 and the surrounding components may be removed.

Furthermore, for the combination of order N and group delay count M in the case of M=N−2, in the signal processors 110-1 to 110-9 among the signal processors 110-1 to 110-10, the single amplifier is used for the two amplifiers for the pair of filter coefficients ai starting from the index i of 0 (that is, a common amplifier is used), and therefore, approximately half (five) of the eleven amplifiers in total, that is, the amplifiers 114 of the signal processors 110-1 to 110-10 and the amplifier 120 illustrated in FIG. 12 and the surrounding components may be removed. More specifically, the amplifier 120 and the amplifier 114 of the signal processor 110-1 are integrated as one common amplifier, the amplifiers 114 of the signal processors 110-2 and 110-3 are integrated as one common amplifier, the amplifiers 114 of the signal processors 110-4 and 110-5 are integrated as one common amplifier, the amplifiers 114 of the signal processors 110-6 and 110-7 are integrated as one common amplifier, and the amplifiers 114 of the signal processors 110-8 and 110-9 are integrated as one common amplifier, so that the number of amplifiers may be reduced to half. In addition, by reducing the number of amplifiers, specifically, the components in front and rear of the amplifiers may also be reduced. Note that specific circuit configurations of the IIR-type all-pass filter 100, which are simplified circuit configurations, with N=10 in cases of M=N−3, M=N−2, and M=N−1 are the same as those of the IIR-type all-pass filter 100 with N=9 in cases of M=N−3, M=N−2, and M=N−1, (FIGS. 7 to 9), and are therefore omitted here.

### <Frequency Characteristic of IIR-Type All-Pass Filter 100 (M=N−3)>

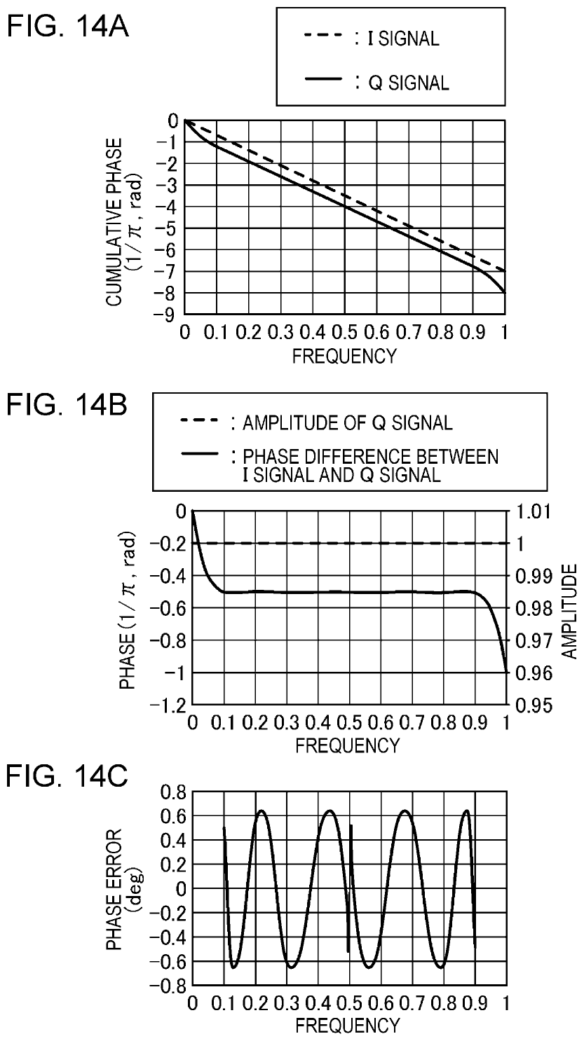

FIGS. 14A to 14C are graphs of examples of the frequency characteristic of the IIR-type all-pass filter 100 with the order N of 10 and M of N−3. In FIG. 14A, an axis of abscissae indicates a frequency and an axis of ordinates indicates a cumulative phase. The frequency on the axis of abscissae is a normalized frequency, and therefore, has no units. The cumulative phase on the axis of ordinates represents the number of 1/π radians (rad). In FIG. 14A, the I signal is indicated by a dashed line and the Q signal is indicated by a solid line.

The I signal output from the digital signal delay circuit 8 (refer to FIG. 1) is characterized by a −7π shift while the frequency changes from 0 to 1. The Q signal is delayed in phase by 90 degrees with respect to the I signal in a frequency band of 0.1 to 0.9 and has a characteristic of a linear change with respect to increase in frequency (x/2 phase shift characteristic). The IIR-type all-pass filter 100 with the frequency characteristic illustrated in FIG. 14A has the order N of 10 and M is N−3, and therefore, a group delay count M is 7 (M=7). In fact, the cumulative phase linearly changes by −5.6 (from −1.2 to −6.8) while the frequency changes from 0.1 to 0.9, and therefore, the group delay count is 7 simultaneously with the I signal.

Furthermore, FIG. 14B is a graph of an example of a frequency characteristic of a phase difference between the I and Q signals. In FIG. 14B, an axis of abscissae represents a normalized frequency, and a left axis of ordinates represents the phase difference between the I and Q signals in 1/π radians (rad). A right axis of ordinates represents an amplitude of the Q signal. In FIG. 14B, the phase difference between the I and Q signals is indicated by a solid line and the amplitude of the Q signal is indicated by a dashed line.

As illustrated in FIG. 14B, in the frequency band of 0.1 to 0.9, the phase difference between the I and Q signals is approximately 0.5 (π/2=90 degrees), and the amplitude of the Q signal is 1.

FIG. 14C is a graph of an example of the frequency characteristic of a phase error of the Q signal. In FIG. 14C, an axis of abscissae represents a normalized frequency, and an axis of ordinates represents a phase error of the Q signal in degrees. The phase error of the Q signal is an error with respect to −90 degrees. As illustrated in FIG. 14C, the phase error of the Q signal for the change in frequency is +0.64 degrees, confirming that the characteristic of preferable equal ripple with equal upper and lower amplitude is obtained. Note that the up and down ripple at a frequency of 0.5 is caused by the convenience of the calculation in the simulation, and an actual phase error characteristic varies continuously with a change in frequency.

### <Frequency Characteristic of IIR-Type All-Pass Filter 100 (M=N−2)>

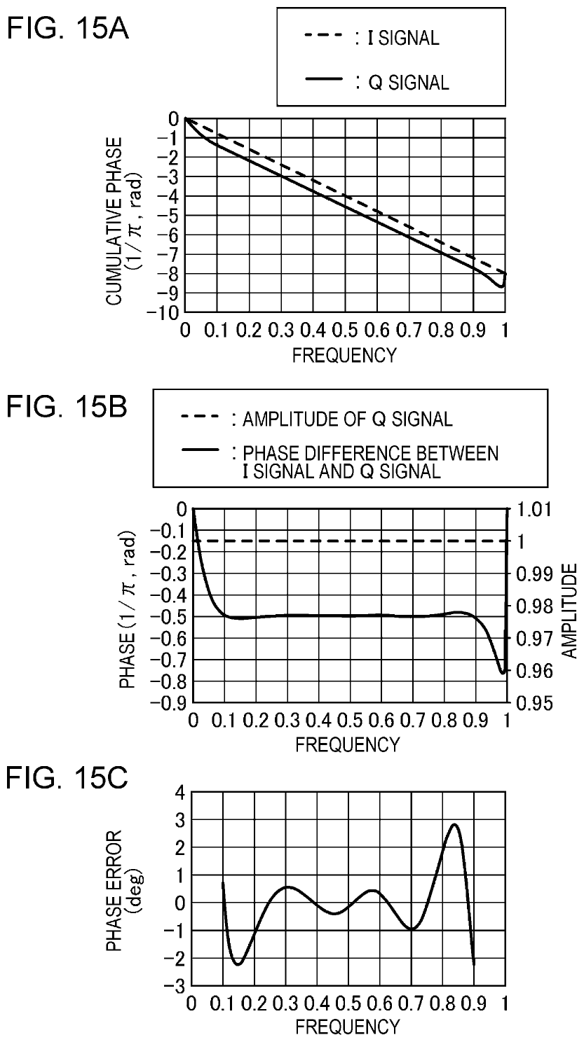

FIGS. 15A to 15C are graphs of examples of the frequency characteristic of the IIR-type all-pass filter 100 with the order N of 10 and M of N−2. In FIG. 15A, an axis of abscissae indicates a frequency and an axis of ordinates indicates a cumulative phase. The frequency on the axis of abscissae is a normalized frequency, and therefore, has no units. The cumulative phase on the axis of ordinates represents the number of 1/π radians (rad). In FIG. 15A, the I signal is indicated by a dashed line and the Q signal is indicated by a solid line.

The I signal output from the digital signal delay circuit 8 (refer to FIG. 1) is characterized by a −8π shift while the frequency changes from 0 to 1. The Q signal is delayed in phase by 90 degrees with respect to the I signal in a frequency band of 0.1 to 0.9 and has a characteristic of a linear change with respect to increase in frequency (x/2 phase shift characteristic). The IIR-type all-pass filter 100 with the frequency characteristic illustrated in FIG. 15A has the order N of 10 and M is N−2, and therefore, a group delay count M is 8 (M=8). In fact, the cumulative phase linearly changes by −6.4 (from −1.3 to −7.7) while the frequency changes from 0.1 to 0.9, and therefore, the group delay count is 8 simultaneously with the I signal.

Furthermore, FIG. 15B is a graph of an example of a frequency characteristic of a phase difference between the I and Q signals. In FIG. 15B, an axis of abscissae represents a normalized frequency, and a left axis of ordinates represents the phase difference between the I and Q signals in 1/π radians (rad). A right axis of ordinates represents an amplitude of the Q signal. In FIG. 15B, the phase difference between the I and Q signals is indicated by a solid line and the amplitude of the Q signal is indicated by a dashed line.

As illustrated in FIG. 15B, in the frequency band of 0.1 to 0.9, the phase difference between the I and Q signals is approximately 0.5 (π/2=90 degrees), and the amplitude of the Q signal is 1.

FIG. 15C is a graph of an example of the frequency characteristic of a phase error of the Q signal. In FIG. 15C, the axis of abscissae represents a normalized frequency, and the axis of ordinates represents a phase error of the Q signal in degrees. The phase error of the Q signal is an error with respect to −90 degrees. As shown in FIG. 15C, the phase error of the Q signal with respect to the change in frequency is +2.86 degrees, which is larger on a positive side, and no characteristic of equal ripple is obtained. Note that, although the phase error is large, the IIR-type all-pass filter 100 may be used for some applications.

### <Frequency Characteristic of IIR-Type All-Pass Filter 100 (M=N−1)>

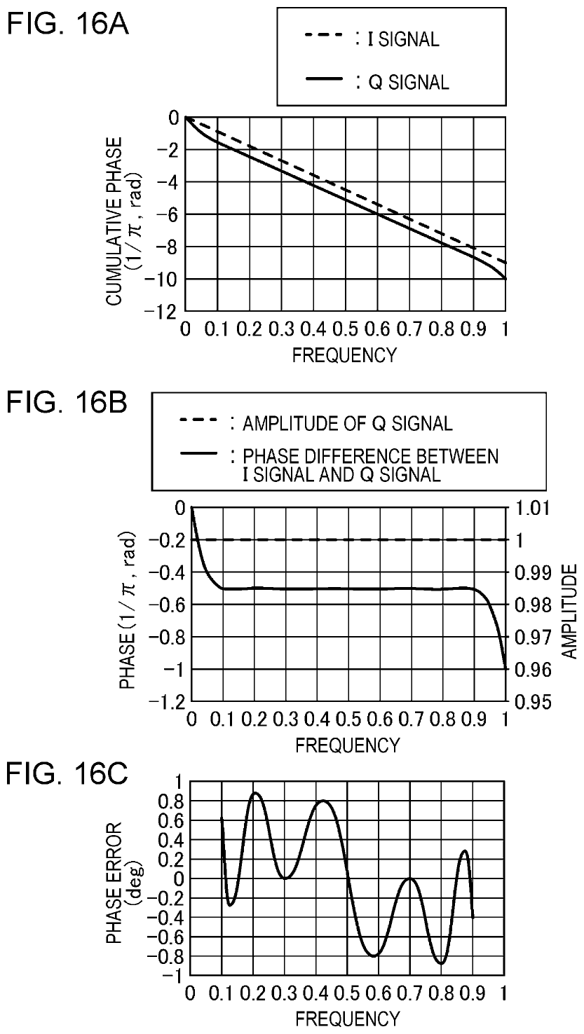

FIGS. 16A to 16C are graphs of examples of the frequency characteristic of the IIR-type all-pass filter 100 with the order N of 10 and M of N−1. In FIG. 16A, an axis of abscissae indicates a frequency and an axis of ordinates indicates a cumulative phase. The frequency on the axis of abscissae is a normalized frequency, and therefore, has no units. The cumulative phase on the axis of ordinates represents the number of 1/π radians (rad). In FIG. 16A, the I signal is indicated by a dashed line and the Q signal is indicated by a solid line.

The I signal output from the digital signal delay circuit 8 (refer to FIG. 1) is characterized by a −9π shift while the frequency changes from 0 to 1. The Q signal is delayed in phase by 90 degrees with respect to the I signal in a frequency band of 0.1 to 0.9 and has a characteristic of a linear change with respect to increase in frequency (x/2 phase shift characteristic). The IIR-type all-pass filter 100 with the frequency characteristic illustrated in FIG. 16A has the order N of 10 and M is N−1, and therefore, a group delay count M is 9 (M=9). In fact, the cumulative phase linearly changes by −7.2 (from −1.4 to −8.6) while the frequency changes from 0.1 to 0.9, and therefore, the group delay count is 9 simultaneously with the I signal.

Furthermore, FIG. 16B is a graph of an example of a frequency characteristic of a phase difference between the I and Q signals. In FIG. 16B, an axis of abscissae represents a normalized frequency, and a left axis of ordinates represents the phase difference between the I and Q signals in 1/π radians (rad). A right axis of ordinates represents an amplitude of the Q signal. In FIG. 16B, the phase difference between the I and Q signals is indicated by a solid line and the amplitude of the Q signal is indicated by a dashed line.

As illustrated in FIG. 16B, in the frequency band of 0.1 to 0.9, the phase difference between the I and Q signals is approximately 0.5 (π/2=90 degrees), and the amplitude of the Q signal is 1.

FIG. 16C is a graph of an example of the frequency characteristic of a phase error of the Q signal. In FIG. 16C, the axis of abscissae represents a normalized frequency, and the axis of ordinates represents a phase error of the Q signal in degrees. The phase error of the Q signal is an error with respect to −90 degrees. As illustrated in FIG. 16C, the phase error of the Q signal for the change in frequency is +0.89 degrees, which is not a characteristic of the equal ripple, confirming that a practically-available amplitude is obtained.

### <Computer System 20 for Realizing Filter Design Method>

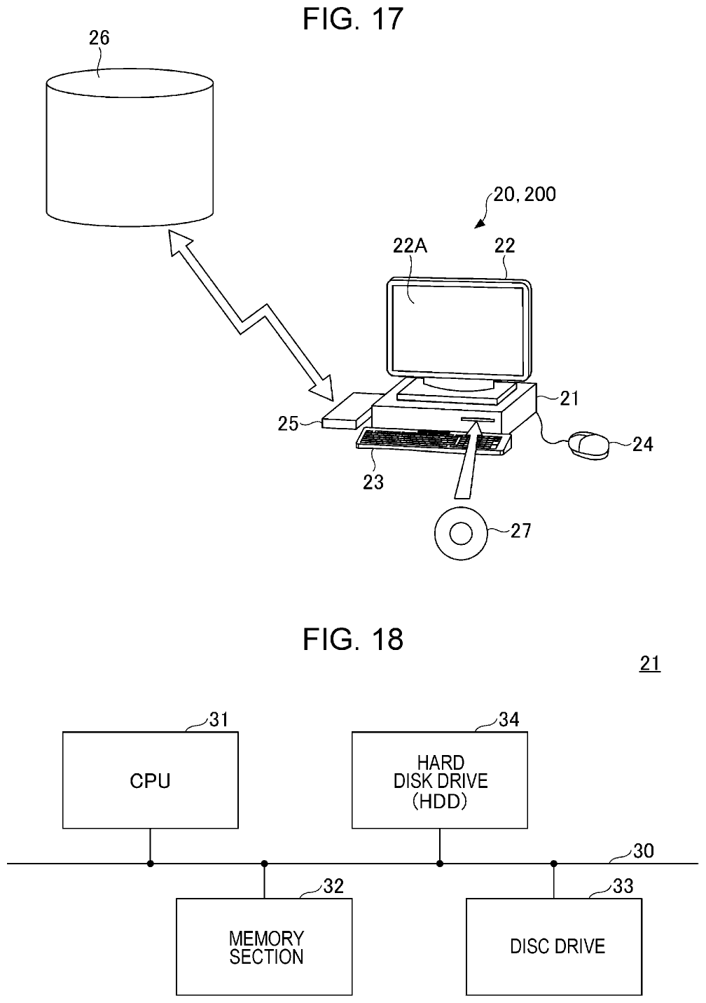

FIG. 17 is a diagram illustrating a computer system 20. The computer system 20 includes a main body 21, a display 22, a keyboard 23, a mouse 24, and a modem 25, and is used as a server on which a filter design program of the embodiment is installed. The filter design method of the embodiment is realized when the filter design program of the embodiment is executed. The computer system 20 functions as a filter design device 200. Therefore, the reference numeral 200 is in parentheses near the reference numeral 20.

The main body 21 incorporates a central processing unit (CPU), a hard disk drive (HDD), and a disc drive. The display 22 displays processing results and other information on a screen 22A based on instructions issued from the main body 21. The display 22 may be, for example, a liquid crystal monitor. The keyboard 23 is an input section for inputting various information to the computer system 20. The mouse 24 is an input section for specifying an arbitrary position on the screen 22A of the display 22. The modem 25 accesses external databases, etc., to download programs, etc., stored in other computer systems.

The filter design program of the embodiment is stored in a portable recording medium, such as a disc 27, or downloaded from a storage medium 26 of another computer system using a communication device, such as the modem 25, and input into the computer system 20 before being compiled. The portable recording medium may be an IC card memory, a magnetic disc, such as a floppy (registered trademark) disc, a magneto-optical disc, a CD-ROM, a universal serial bus (USB) memory, or the like. Furthermore, instead of the portable recording medium, a computer-readable recording medium accessible by a computer system connected via a communication device, such as the modem 25 or a local area network (LAN), may be used.

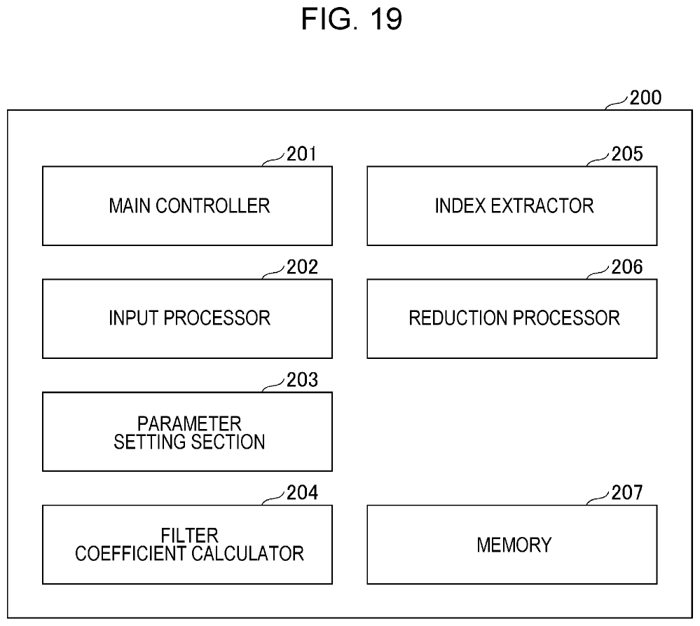

FIG. 18 is a block diagram illustrating a configuration of an important portion in the main body 21 of the computer system 20. The main body 21 includes a CPU 31, a memory section 32 including a RAM or a ROM, a disc drive 33 for the disc 27, and a hard disk drive (HDD) 34, which are connected to one another via a bus 30. Note that the computer system 20 is not limited to the configuration illustrated in FIGS. 17 and 18, and various known elements may be added or used alternatively.

### <Functional Block>

FIG. 19 is a functional block diagram of the filter design device 200. When executing the filter design program, the computer system 20 functions as the filter design device 200.

The filter design device 200 has a main controller 201, an input processor 202, a parameter setting section 203, a filter coefficient calculator 204, an index extractor 205, a reduction processor 206, and a memory 207. The main controller 201, the input processor 202, the parameter setting section 203, the filter coefficient calculator 204, the index extractor 205, and the reduction processor 206 represent functions of the filter design program executed by the computer system 20 as functional blocks. Furthermore, the memory 207 functionally indicates a memory of the computer system 20.

The main controller 201 is a processor that controls processing of the filter design device 200 and executes processes other than those executed by the input processor 202, the parameter setting section 203, the filter coefficient calculator 204, the index extractor 205, and the reduction processor 206.

The input processor 202 performs a process of accepting inputs of the order N and the design bandwidth B of the IIR-type all-pass filter. The order N and the design bandwidth B are input by the user using the keyboard 23 and the mouse 24.

The parameter setting section 203 performs a process of setting a frequency low limit fl and a frequency high limit fh using the design bandwidth B.

The filter coefficient calculator 204 calculates filter coefficients ai (i=0 to N) including N filter coefficients a1 to aN by which outputs of the N signal processors 110-1 to 110-N are multiplied and a filter coefficient a0 by which an output of the delay device 111 of the N-th signal processor 110-N from the input terminal 101 is multiplied such that the filter coefficients ai realizes a π/2 shift characteristic, that is, performs a process of calculating the filter coefficients ai based on Remez algorithm until a change in frequency at which an amplitude value of a complex amplitude error indicates an extreme value converges on a predetermined value or below.

When the index extractor 205 extracts a maximum value of the filter coefficient ai and an index i of the filter coefficient ai that gives a maximum value (imax), the filter coefficient calculator 204 performs the following process.

The filter coefficient calculator 204 performs, in a case where the group delay count M is the order N−3, a process of setting the filter coefficients ai with even-numbered indices i to zero when the order N is an odd number and the index imax is 1, and setting the filter coefficients ai with odd-numbered indices i to zero when the order N is an even number and the index imax is 0.

The filter coefficient calculator 204 performs, in a case where the group delay count M is the order N−1, a process of setting the filter coefficients ai with the odd-numbered indices i to zero when the index imax is 0.

The filter coefficient calculator 204 performs, in a case where the group delay count M is the order N−2, a process of setting each pair of filter coefficients ai starting from the index i of 0 to have the same value (an average value of the pair of filter coefficients) when the index imax is 0 or 1.

The index extractor 205 performs a process of extracting a maximum value of the filter coefficient ai and the index i of the filter coefficient ai that gives the maximum value (imax).

The reduction processor 206 performs a process of reducing the number of components of the signal processors corresponding to the index i having the filter coefficient ai of zero among the signal processors 110-1 to 110-N, or a process of reducing components of one of two signal processors corresponding to the index i having the filter coefficients ai of the same value among the signal processors 110-1 to 110-N.

The memory 207 stores the filter design program. The memory 207 stores not only the calculated filter coefficients ai but also data required for performing processing by the main controller 201, the input processor 202, the parameter setting section 203, the filter coefficient calculator 204, the index extractor 205, and the reduction processor 206, and data generated in the processing.

### Calculation in Filter Design Method

Next, a calculation method for designing the IIR-type all-pass filter 100 will be described. This calculation is performed by the filter coefficient calculator 204.

First, Ad is obtained according to Expression (1) below. Ad indicates a frequency characteristic of a π/2-shifted all-pass filter with a constant group delay characteristic, which is a desired characteristic to aim for in filter design. Here, f is a normalized frequency, which corresponds to the frequency on the axes of abscissae in FIGS. 3, 4, 5, 10, 11, 14, 15, and 16. The frequency f takes the range 0≤f≤1, where f=1 is the Nyquist frequency. Also, j is an imaginary unit (√−1).

$${A}_{d} ( f ) = {e}^{j {θ}_{d} ( f )} \qquad ( 1 )$$

Here, Od in Expression (1) denotes a desired cumulative phase of the Q signal and is expressed in Expression (2). A phase of the Q signal is delayed relative to a phase of the I signal (−πMf) by π/2.

$${θ}_{d} ( f ) = - π Mf - π / 2 \qquad ( 2 )$$

The frequency characteristic of the IIR-type all-pass filter 100 is calculated by Expression (3) below.

$$A ( f ) = {e}^{- j π Nf} \frac{{\sum }_{i = 0}^{N} {a}_{i} {e}^{j π if}}{{\sum }_{i = 0}^{N} {a}_{i} {e}^{- j π if}} \qquad ( 3 )$$

An evaluation function to evaluate an amplitude error as a complex amplitude error is defined as a difference between Expression (1) and Expression (3) and is expressed as Expression (4) below.

$$( 4 )$$

$$E ( f ) = \text{} A ( f ) - {A}_{d} ( f ) = {e}^{j ( {θ}_{d} ( f ) - π Nf ) / 2} \frac{- j 2 {\sum }_{i = 0}^{N} {a}_{i} sin [ \frac{{θ}_{d} ( f ) + π Nf - 2 π if}{2} ]}{{\sum }_{i = 0}^{N} {a}_{i} {e}^{- j π if}}$$

The filter coefficients ai are best approximated using Expression (5) below so that an amplitude value E*(f) of the error function is equal to or smaller than a predetermined value.

$${E}^{*} ( f ) = \frac{2 {\sum }_{i = 0}^{N} {a}_{i} sin [ \frac{{θ}_{d} ( f ) + π Nf - 2 π if}{2} ]}{\vert D ( f ) \vert} \qquad ( 5 )$$

Here, |D(f)| in Expression (5) is calculated based on Expression (6) below.

$$\vert D ( f ) \vert = {[ {\{ {\sum }_{i = 0}^{N} {a}_{i} cos ( π if ) \}}^{2} + {\{ {\sum }_{i = 0}^{N} {a}_{i} sin ( π if ) \}}^{2} ]}^{1 / 2} \qquad ( 6 )$$

To ensure that the amplitude value E*(f) of the error function is equal to or smaller than the predetermined value, specifically, the filter coefficients are optimized using Expression (7) so that the amplitude value E*(f) of the error function becomes equal ripple at a frequency point fk (k is 0 to N).

$${E}^{*} ( {f}_{k} ) = {( - 1 )}^{k} δ \qquad ( 7 )$$

Expression (7) is developed as an expression with the filter coefficients ai to obtain Expression (8) below. The Index i is from 0 to N and δ is a predetermined value.

$${\sum }_{i = 0}^{N} {a}_{i} sin [ \frac{{θ}_{d} ( {f}_{k} ) + π {Nf}_{k} - 2 π {if}_{k}}{2} ] = \frac{{( - 1 )}^{k} δ \vert D ( {f}_{k} ) \vert}{2} \qquad ( 8 )$$

Formulating Expression (8) for N+1 frequency points fk and organizing a resultant with respect to the filter coefficients ai, a further resultant may be expressed as a matrix as in Expression (9) below, from which the filter coefficients ai may be obtained.

$$[ \begin{matrix}{S}_{00} & {S}_{10} & … & {S}_{0 N} \\ {S}_{10} & {S}_{11} & … & {S}_{1 N} \\ ⋮ & ⋮ & ⋱ & ⋮ \\ {S}_{N 0} & {S}_{N 1} & … & {S}_{NN}\end{matrix} ] [ \begin{matrix}{a}_{0} \\ {a}_{1} \\ ⋮ \\ {a}_{N}\end{matrix} ] = [ \begin{matrix}{( - 1 )}^{0} δ \vert D ( {f}_{0} ) \vert / 2 \\ {( - 1 )}^{1} δ \vert D ( {f}_{1} ) \vert / 2 \\ ⋮ \\ {( - 1 )}^{N} δ \vert D ( {f}_{N} ) \vert / 2\end{matrix} ] \qquad ( 9 )$$

Here, Ski in Expression (9) is expressed by Expression (10) below. The index i is from 0 to N, and an index k is also from 0 to N.

$${S}_{ki} = sin ( \frac{{θ}_{d} ( {f}_{k} ) + π {Nf}_{k} - 2 π {if}_{k}}{2} ) \qquad ( 10 )$$

By performing the above calculations, for example, the filter coefficients ai illustrated in FIGS. 6 and 13 may be obtained.

### <Flowchart (M=N−3)>

FIG. 20 is a flowchart of a process performed by the filter design device 200. Here, the group delay count M will be described here for a case M=N−3.

When a process starts, the input processor 202 performs a process of accepting inputs of the order N and the design bandwidth B of the IIR-type all-pass filter 100 as design conditions (step S10). The order N is equal to or larger than 4, and the design bandwidth B is larger than 0 and smaller than 1(0<B<1).

The parameter setting section 203 performs a process of setting design parameters (step S11). The design parameters are the frequency low limit fl, the frequency high limit fh, and the group delay count M. Here, the group delay count M is N−3. The frequency low limit fl and the frequency high limit fh are obtained by Expression (11) below. Here, the frequency low limit fl and the frequency high limit fh are set so as to have the same bandwidths around a frequency of 0.5, which is one half of the Nyquist frequency. It is the same as settings of the frequency low limit fl and the frequency high limit fh so that a result of adding the frequency low limit fl and the frequency high limit fh is equal to the Nyquist frequency 1.

$$fl = 0.5 - \frac{B}{2} \qquad ( 11 )$$

$$fh = 0.5 + \frac{B}{2}$$

The filter coefficient calculator 204 sets initial design values (step S12). Specifically, the filter coefficient calculator 204 sets frequency points fk at equal intervals between fl and fh. Here k=0 to N. The filter coefficient calculator 204 initializes |D(fk)| at 1.0.

The filter coefficient calculator 204 calculates the filter coefficients ai with a π/2 shift characteristic in the IIR-type all-pass filter using Expressions (9) and (10) (step S13). Here, i=0 to N.

The index extractor 205 extracts the maximum value amax and the index imax of the filter coefficient ai that gives the maximum value among the filter coefficients a0 to aN calculated in step S13 (step S14).

The filter coefficient calculator 204 determines whether the order N is an odd number (step S15).

When determining that the order N is an odd number (S15: YES), the filter coefficient calculator 204 determines whether the index imax is 1 (step S16).

When determining that the index imax is 1 (S16: YES), the filter coefficient calculator 204 sets a value of the filter coefficient ai having the index i of an even number to zero (step S17). For example, the filter coefficients a0, a2, a4, a6, and a8 are set to zero, as in the calculation results for M=N−3 in FIG. 6. After the filter coefficient calculator 204 finishes the process in step S17, the flow proceeds to step S20, but before that, steps S18 and S19 will be described.

When determining that the order N is not an odd number in step S15 (S15: NO), the filter coefficient calculator 204 determines whether the index imax is 0 (step S18).

When determining that the index imax is 0 (S18: YES), the filter coefficient calculator 204 sets a value of the filter coefficient ai having the index i of an odd number to zero (step S19). For example, the filter coefficients a1, a3, a5, a7, and a9 are set to zero, as in the calculation results for M=N−3 in FIG. 13. The filter coefficient calculator 204 proceeds to step S20 after completing the process in step S19. Also when determining that the index imax is not 0 in step S18 (S18: NO), the filter coefficient calculator 204 proceeds to step S20.

The filter coefficient calculator 204 normalizes the values of the filter coefficients ai by the maximum value amax (step S20). This is performed on all the filter coefficients ai (i=0 to N).

The filter coefficient calculator 204 calculates the amplitude value E*(f) of the error function in accordance with Expressions (5) and (6). Here, a plurality of frequency points that satisfy the relationship fl≤f≤fh are assigned to f in Expressions (5) and (6) for calculation. With reference to the plurality of calculated amplitude values E*(f), frequencies that indicate a local maximum value and a local minimum value are searched for, and are stored in fpk (step S21). Here, k=0 to N. Here, the plurality of frequency points are preferably set at a granularity sufficient to discriminate the local maximum value and the local minimum value of the amplitude value E*(f).

The filter coefficient calculator 204 calculates differences Δfk between the frequency points fk and the frequencies fpk and searches for a maximum value Δfkmax of the differences Δfk (k=0 to N) (step S22). That is, Δfk=|fk-fpk| and k=0 to N.

The filter coefficient calculator 204 determines whether the maximum value Δfkmax is equal to or smaller than a predetermined value (step S23).

When determining that the maximum value Δfkmax is equal to or smaller than the predetermined value (S23: YES), the filter coefficient calculator 204 stores the filter coefficients ai (i=0 to N) in the memory 207 (step S24).

The filter coefficient calculator 204 terminates the series of processes (END) after completing the process in step S24.

Furthermore, when determining, in step S23, that the maximum value Δfkmax is not equal to or smaller than the predetermined value (S23: NO), the filter coefficient calculator 204 updates the frequency points fk (k=0 to N) with the frequency fpk (k=0 to N) (step S25). That is, the frequency points f0 to fN are updated to frequencies fp0 to fpN, respectively.

The filter coefficient calculator 204 assigns the frequency points fk to f using Expression (6) so as to calculate the following expression: |D(fk)|(k=0 to N) (step S26). The filter coefficient calculator 204 returns to step S13 after completing the process in step S26. The processes in step S13, step S14, and steps S20 to S26 are performed in accordance with the Remez algorithm.

The above process identifies the filter coefficients ai that are set to zero when the order N is an odd-number or an even-number at M=N−3.

The reduction processor 206 reduces the components of the signal processors 110-i corresponding to the indices i of the filter coefficients ai set to zero in the process of FIG. 20. For example, when N is 9, the circuit configuration illustrated in FIG. 2B is simplified by the reduction processor 206 to the circuit configuration illustrated in FIG. 7.

### <Flowchart (M=N−2)>

FIG. 21 is a flowchart of a process performed by the filter design device 200. Here, the group delay count M will be described here for a case M=N−2.

When a process starts, the input processor 202 performs a process of accepting inputs of the order N and the design bandwidth B of the IIR-type all-pass filter 100 as design conditions (step S110). The order N is equal to or larger than 4, and the design bandwidth B is larger than 0 and smaller than 1 (0<B<1). The process in step S110 is the same as the process in step S10 in FIG. 20.

The parameter setting section 203 performs a process of setting design parameters (step S111). The design parameters are the frequency low limit fl, the frequency high limit fh, and the group delay count M. Here, the group delay count M is N−2. The frequency low limit fl and the frequency high limit fh are obtained by Expression (12) below. The process in step S111 is the same as the process in step S11 in FIG. 20 except for the setting of the group delay count M.

$$fl = 0.5 - \frac{B}{2} \qquad ( 12 )$$

$$fh = 0.5 + \frac{B}{2}$$

The filter coefficient calculator 204 sets initial design values (step S112). Specifically, the filter coefficient calculator 204 sets frequency points fk at equal intervals between fl and fh. Here k=0 to N. The filter coefficient calculator 204 initializes |D(fk)| at 1.0. The process in step S112 is the same as the process in step S12 in FIG. 20.

The filter coefficient calculator 204 calculates the filter coefficients ai with a π/2 shift characteristic in the IIR-type all-pass filter using Expressions (9) and (10) (step S113). Here, i=0 to N. The process in step S113 is the same as the process in step S13 in FIG. 20.

The index extractor 205 extracts the maximum value amax and the index imax of the filter coefficient ai that gives the maximum value among the filter coefficients a0 to aN calculated in step S113 (step S114). The process in step S114 is the same as the process in step S14 in FIG. 20.

The filter coefficient calculator 204 determines whether the index imax is 1 (step S115).

When determining that the index imax is not 1 (S115: NO), the filter coefficient calculator 204 determines whether the index imax is 0 (step S116).

When determining that the index imax is 0 (S116: YES), the filter coefficient calculator 204 proceeds to step S117.

When determining that the index imax is 1 in step S115 (S115: YES), the filter coefficient calculator 204 sets (updates) each pair of filter coefficients ai starting from the index i of 0 to an average value of the pair of filter coefficients ai (step S117). For example, for the filter coefficients a0 and a1, V01=(a0+a1)/2 is calculated and a new filter coefficient a0 is set as V01. Similarly, for the filter coefficients a2 and a3, V23=(a2+a3)/2 is calculated and a new filter coefficient a1 is set as V23. The same applies hereinafter.

The filter coefficient calculator 204 updates the maximum value amax of the filter coefficients ai (i=0 to N) to the average value V01 (step S118). That is, amax=V01=(a0+a1)/2 is satisfied.

The filter coefficient calculator 204 normalizes the values of the filter coefficients ai by the maximum value amax (step S120). This is performed on all the filter coefficients ai (i=0 to N). The process in step S120 is the same as the process in step S20 in FIG. 20.

The filter coefficient calculator 204 calculates the amplitude value E*(f) of the error function in accordance with Expressions (5) and (6). Here, a plurality of frequency points that satisfy the relationship fl≤f≤fh are assigned to f in Expressions (5) and (6) for calculation. With reference to the plurality of calculated amplitude values E*(f), frequencies that indicate a local maximum value and a local minimum value are searched for, and are stored in fpk (step S121). Here, k=0 to N. Here, the plurality of frequency points are preferably set at a granularity sufficient to discriminate the local maximum value and the local minimum value of the amplitude value E*(f). The process in step S121 is the same as the process in step S21 in FIG. 20.

The filter coefficient calculator 204 calculates differences Δfk between the frequency points fk and the frequencies fpk and searches for a maximum value Δfkmax of the differences Δfk (k=0 to N) (step S122). That is, Δfk=|fk-fpk|, where k=0 to N. The process in step S122 is the same as the process in step S22 in FIG. 20.

The filter coefficient calculator 204 determines whether the maximum value Δfkmax is equal to or smaller than a predetermined value (step S123). The process in step S123 is the same as the process in step S23 in FIG. 20.

When determining that the maximum value Δfkmax is equal to or smaller than the predetermined value (S123: YES), the filter coefficient calculator 204 stores the filter coefficients ai (i=0 to N) in the memory 207 (step S124). The process in step S124 is the same as the process in step S24 in FIG. 20.

The filter coefficient calculator 204 terminates the series of processes (END) after completing the process in step S124.

Furthermore, when determining, in step S123, that the maximum value Δfkmax is not equal to or smaller than the predetermined value (S123: NO), the filter coefficient calculator 204 updates the frequency points fk (k=0 to N) with the frequency fpk (k=0 to N) (step S125). That is, the frequency points f0 to fN are updated to frequencies fp0 to fpN, respectively. The process in step S125 is the same as the process in step S25 in FIG. 20.

The filter coefficient calculator 204 assigns the frequency points fk to f using Expression (6) so as to calculate the following expression: |D(fk)|(k=0 to N) (step S126). The filter coefficient calculator 204 returns to step S113 after completing the process in step $126. The processes in step S113, step S114, and steps S120 to S126 are performed in accordance with the Remez algorithm.

The above process identifies the filter coefficients ai that are set to the same value two by two when the order N is an odd-number or an even-number at M=N−2.

The reduction processor 206 reduces one of the components of the two signal processors 110-i corresponding to the index i for which the filter coefficients ai are set to the same value in the process in FIG. 21. For example, when N is 9, the circuit configuration illustrated in FIG. 2A is simplified by the reduction processor 206 to the circuit configuration illustrated in FIG. 8.

Note that the values for the case M=N=9 illustrated in FIG. 6 and the values for the case M=N=10 illustrated in FIG. 13 are calculated by setting M=N in step S111 in the flow illustrated in FIG. 21, performing the process in step S114, and then proceeding to step S120 without performing the processes in steps S115, S117, and S118.

### <Flowchart (M=N−1)>

FIG. 22 is a flowchart of a process performed by the filter design device 200. Here, the group delay count M will be described here for a case M=N−1.

When a process starts, the input processor 202 performs a process of accepting inputs of the order N and the design bandwidth B of the IIR-type all-pass filter 100 as design conditions (step S210). The order N is equal to or larger than 4, and the design bandwidth B is larger than 0 and smaller than 1 (0<B<1). The process in step S210 is the same as the process in step S10 in FIG. 20.

The parameter setting section 203 performs a process of setting design parameters (step S211). The design parameters are the frequency low limit fl, the frequency high limit fh, and the group delay count M. Here, the group delay count M is N−1. The frequency low limit fl and the frequency high limit fh are obtained by Expression (13) below. The process in step S211 is the same as the process in step S11 in FIG. 20 except for the setting of the group delay count M.

$$fl = 0.5 - \frac{B}{2} \qquad ( 13 )$$

$$fh = 0.5 + \frac{B}{2}$$

The filter coefficient calculator 204 sets initial design values (step S212). Specifically, the filter coefficient calculator 204 sets frequency points fk at equal intervals between fl and fh. Here, k=0 to N. The filter coefficient calculator 204 initializes |D(fk)| at 1.0. The process in step S212 is the same as the process in step S12 in FIG. 20.

The filter coefficient calculator 204 calculates the filter coefficients ai with a π/2 shift characteristic in the IIR-type all-pass filter using Expressions (9) and (10) (step S213). Here, i=0 to N. The process in step S213 is the same as the process in step S13 in FIG. 20.

The index extractor 205 extracts the maximum value amax and the index imax of the filter coefficient ai that gives the maximum value among the filter coefficients a to aN calculated in step S213 (step S214). The process in step S214 is the same as the process in step S14 in FIG. 20.

The filter coefficient calculator 204 determines whether the index imax is 0 (step S218).

When determining that the index imax is 0 (S218: YES), the filter coefficient calculator 204 sets a value of the filter coefficient ai having the index i of an odd number to zero (step S219). For example, the filter coefficients a1, a3, a5, a7, and a9 are set to zero, as in the calculation results for M=N−1 in FIG. 6. When the filter coefficient calculator 204 terminates the process in step S219, the flow proceeds to step S220. In step S218, when the filter coefficient calculator 204 determines that the index imax is not 0 (S218: NO), the flow also proceeds to step S220.

The filter coefficient calculator 204 normalizes the values of the filter coefficients ai by the maximum value amax (step S220). This is performed on all the filter coefficients ai (i=0 to N). The process in step S220 is the same as the process in step S20 in FIG. 20.

The filter coefficient calculator 204 calculates the amplitude value E*(f) of the error function in accordance with Expressions (5) and (6). Here, a plurality of frequency points that satisfy the relationship fl≤ f≤ fh are assigned to fin Expressions (5) and (6) for calculation. With reference to the plurality of calculated amplitude values E*(f), frequencies that indicate a local maximum value and a local minimum value are searched for, and are stored in fpk (step S221). Here, k=0 to N. Here, the plurality of frequency points are preferably set at a granularity sufficient to discriminate the local maximum value and the local minimum value of the amplitude value E*(f). The process in step S221 is the same as the process in step S21 in FIG. 20.

The filter coefficient calculator 204 calculates differences Δfk between the frequency points fk and the frequencies fpk and searches for a maximum value Δfkmax of the differences Δfk (k=0 to N) (step S222). That is, Δfk=|fk-fpk|, where k=0 to N. The process in step S222 is the same as the process in step S22 in FIG. 20.

The filter coefficient calculator 204 determines whether the maximum value Δfkmax is equal to or smaller than a predetermined value (step S223). The process in step S223 is the same as the process in step S23 in FIG. 20.

When determining that the maximum value Δfkmax is equal to or smaller than the predetermined value (S223: YES), the filter coefficient calculator 204 stores the filter coefficients ai (i=0 to N) in the memory 207 (step S224). The process in step S224 is the same as the process in step S24 in FIG. 20.

The filter coefficient calculator 204 terminates the series of processes (END) after completing the process in step S224.

Furthermore, when determining, in step S223, that the maximum value Δfkmax is not equal to or smaller than the predetermined value (S223: NO), the filter coefficient calculator 204 updates the frequency points fk (k=0 to N) with the frequency fpk (k=0 to N) (step S225). That is, the frequency points f0 to fN are updated to frequencies fp0 to fpN, respectively. The process in step S225 is the same as the process in step S25 in FIG. 20.

The filter coefficient calculator 204 assigns the frequency points fk to f using Expression (6) so as to calculate the following expression: |D(fk)|(k=0 to N) (step S226). The filter coefficient calculator 204 returns to step S213 after completing the process in step S226. The processes in step S213, step S214, and steps S220 to S226 are performed in accordance with the Remez algorithm.

The above process identifies the filter coefficients ai that are set to zero when the order N is an odd-number or an even-number at M=N−1.

The reduction processor 206 reduces the components of the signal processors 110-i corresponding to the indices i of the filter coefficients ai set to zero in the process of FIG. 22. For example, when N is 9, the circuit configuration illustrated in FIG. 2A is simplified by the reduction processor 206 to the circuit configuration illustrated in FIG. 9.

As described above, when the order N is 9 or 10 and the group delay count M is N−3 or N−1, a number of the filter coefficients ai are set to zero, and the number of components of the signal processor 110-i corresponding to the index i of the filter coefficient ai set to zero may be reduced. Furthermore, when the order N is 9 or 10 and the group delay count M is N−2, the pairs of filter coefficients ai are set to the same value each, and the number of components of one of the two signal processors 110-i corresponding to the index i for which the filter coefficient ai is set to the same value may be reduced.

Therefore, a filter design method and the IIR-type all-pass filter 100 that enables reduction of the number of components may be provided.

Note that, although the cases of the order N of 9 and 10 are described hereinabove, it has been confirmed that the number of components that may be reduced is up to approximately 80 when the order N is 4 or higher. Since the order N may cover up to a range of approximately 80, it is possible to design to reduce the number of components for almost any order N of IIR-type all-pass filter 100 that is practically available.

The above describes the filter design method and the IIR-type all-pass filter according to the exemplary embodiment of the present disclosure. However, the present disclosure is not limited to the specifically disclosed embodiment, and various modifications and changes may be made without departing from the scope of the claims.

What is claimed is:

1. A filter design method in which a computer designs an IIR-type all-pass filter including N (N is an integer of 4 or more) signal processors connected between an input terminal and an output terminal, wherein
a group delay count M of the IIR-type all-pass filter has the relationship “M=N−3” with respect to the order N defined by the number N of signal processors, and
the computer executes a process including
accepting inputs of the order N and a bandwidth of the IIR-type all-pass filter,
setting a frequency low limit and a frequency high limit which are symmetrical using the bandwidth,
calculating filter coefficients ai (i=0 to N) including N filter coefficients a1 to aN by which outputs of the N signal processors are multiplied and a filter coefficient a0 by which an output of a delay device of the N-th signal processor counting from the input terminal is multiplied such that the filter coefficients ai realizes a π/2 shift characteristic, and calculating the filter coefficients ai based on the Remez algorithm until a change in frequency at which an amplitude value of a complex amplitude error indicates an extreme value converges to or below a predetermined value,
extracting a maximum value of the filter coefficients ai and an index i of the filter coefficient ai that gives the maximum value (imax), and
setting the filter coefficients ai with even-numbered indices i to zero when the order N is an odd number and the index imax is 1, and setting the filter coefficients ai with odd-numbered indices i to zero when the order N is an even number and the index imax is 0.

2. A filter design method in which a computer designs an IIR-type all-pass filter including N (N is an integer of 4 or more) signal processors connected between an input terminal and an output terminal, wherein
the group delay count M of the IIR-type all-pass filter has the relationship “M=N−1” with respect to the order N defined by the number N of signal processors, and
the computer executes a process including
accepting inputs of the order N and a bandwidth of the IIR-type all-pass filter,
setting a frequency low limit and a frequency high limit which are symmetrical using the bandwidth,
calculating filter coefficients ai (i=0 to N) including N filter coefficients a1 to aN by which outputs of the N signal processors are multiplied and a filter coefficient a0 by which an output of a delay device of the N-th signal processor counting from the input terminal is multiplied such that the filter coefficients ai realizes a π/2 shift characteristic, and calculating the filter coefficients ai based on the Remez algorithm until a change in frequency at which an amplitude value of a complex amplitude error indicates an extreme value converges to or below a predetermined value,
extracting a maximum value of the filter coefficients ai and an index i of the filter coefficient ai that gives the maximum value (imax), and
setting the filter coefficients ai with odd-numbered indices to zero, when the index imax is 0,

3. The filter design method according to claim 1, further comprising reducing the number of components of the signal processor corresponding to the index i for which the filter coefficient ai is set to zero in the N signal processors.

4. A filter design method in which a computer designs an IIR-type all-pass filter including N (N is an integer of 4 or more) signal processors connected between an input terminal and an output terminal, wherein
the group delay count M of the IIR-type all-pass filter has the relationship “M=N−2” with respect to the order N defined by the number N of signal processors, and
the computer executes a process including
accepting inputs of the order N and a bandwidth of the IIR-type all-pass filter,
setting a frequency low limit and a frequency high limit which are symmetrical using the bandwidth,
calculating filter coefficients ai (i=0 to N) including N filter coefficients a1 to aN by which outputs of the N signal processors are multiplied and a filter coefficient a0 by which an output of a delay device of the N-th signal processor counting from the input terminal is multiplied such that the filter coefficients ai realizes a π/2 shift characteristic, and calculating the filter coefficients ai based on the Remez algorithm until a change in frequency at which an amplitude value of a complex amplitude error indicates an extreme value converges to or below a predetermined value,
extracting a maximum value of the filter coefficients ai and an index i of the filter coefficient ai that gives the maximum value (imax), and
setting the same value to each pair of filter coefficients ai starting from the index i of 0 when the index imax is 0 or 1.

5. The filter design method according to claim 4, wherein the process further includes reducing components of one of the two signal processors corresponding to the index i of the N signal processors to which the same filter coefficients ai is set.

6. The IIR-type all-pass filter designed by the filter design method described in claim 1.
